(19) United States
(12) Patent Application Publication
(10) Pub. No.: US 2022/0019145 A1
(43) Pub. Date: Jan. 20, 2022

(54) FLEXOGRAPHIC PRINTING PLATE PRECURSOR, IMAGING ASSEMBLY AND USE

(71) Applicant: MIRACLON CORPORATION, Oakdale, MN (US)

(72) Inventors: Alavi KARIM, Woodbury, MN (US); Arsen STEPANOV, Saint Paul, MN (US); M. Zaki ALI, Mendota Heights, MN (US)

(21) Appl. No.: 16/931,436

(22) Filed: Jul. 16, 2020

(51) Int. Cl. G03F 7/11; C09D 133/10; G03F 7/033

(52) U.S. Cl. CPC G03F 7/11; G03F 7/2002; G03F 7/033; C09D 133/10

(57) ABSTRACT

A relief-forming precursor includes a substrate and a relief-forming layer having: a polymer; at least one photopolymerizable monomer; a photopolymerization initiator; and a low surface energy monomer. A relief-forming assembly includes a relief-forming precursor having a low surface energy monomer and a mask element that is in complete optical contact with the relief-forming surface. A method of making a relief image includes: exposing the relief-forming layer to curing UV radiation through the mask element to form an imaged relief-forming layer with polymerized regions and non-polymerized regions; removing the mask element from the imaged relief-forming layer; and developing the imaged relief-forming layer by removing the non-polymerized regions, thereby forming a relief image. A relief image layer has an elastomer and copolymer that includes at least one photopolymerized monomer and a low surface energy monomer that has a silicone moiety with a relief surface having the silicone moiety.

### BACKGROUND

### Field

The present disclosure relates to a flexographic printing plate precursor, imaging assembly, and methods of making and using the same. More particularly, the present disclosure relates to a photosensitive layer of a relief-forming precursor that is configured to have reduced peel force and so that the resulting relief image has reduced surface energy.

### Description of Related Art

Previously, photosensitive materials have been combined with masks in flexographic printing plate precursors. However, removal of the mask from the photosensitive relief-forming layer may not be easily performed without damaging the mask or the photosensitive relief-forming layer. Often, the photosensitive relief-forming layer can be damaged during the process of removing the mask. Damaged photosensitive relief-forming layers are not useful for flexographic printing plates due to the artifacts that result from the damage. As a result, research continues to develop a technology to improve the ability to successfully remove a mask from a photosensitive relief-forming layer without causing any damage.

Photosensitive relief-forming materials having a relief-forming material or photosensitive layer are known in the art. Important advances in the art and useful materials for making flexographic relief images are described in U.S. Patent Application Publication 2005/0227182 (Ali et al., hereinafter cited as U.S. '182). U.S. '182 describes suitable mask element precursors, photosensitive materials for relief-forming layers, and processes and apparatus for forming a mask element from a mask precursor and eventual relief image from a photosensitive relief-forming precursor material.

Typically, a mask element can be placed in intimate contact with a photosensitive relief-forming precursor material using a laminator device or vacuum drawdown, or both, and subjected to overall exposure with actinic radiation (for example, UV radiation) to cure the photosensitive composition in the relief-forming precursor material in the unmasked areas, thus forming a negative image of the mask element in the photosensitive relief-forming precursor. The mask element can then be removed and the uncured regions on the relief-forming material can be removed using a development process. After drying, the resulting imaged relief-forming precursor has a relief image that can be used for flexographic or letterpress printing operations.

Advances in mask element precursors are described in U.S. Pat. No. 7,799,504 (Zwadlo et al.). Other useful mask element precursors and processes for their use are described in U.S. Pat. No. 8,198,012 (Zwadlo et al.), U.S. Pat. No. 8,945,813 (Kidnie), and U.S. Pat. No. 9,250,527 (Kidnie). Advances in photosensitive materials are described in U.S. No. 2019/0258154 (Kidnie). U.S. Pat. No. 8,530,142 (Zwadlo) describes a photopolymer plate precursor which contains a low surface energy release layer over the photosensitive layer to help delamination. U.S. Pat. No. 10,207,491 (Ali et. al.) describes the method of making a flexographic printing plate comprising lamination of a mask image to a flexographic printing plate precursor, UV exposure to form a relief pattern, and delamination of the mask from the photosensitive layer. U.S. Pat. No. 9,114,601 (Baldwin et al.) describes a flexographic printing plate precursor consisting of two photosensitive layers, having a low surface energy silicone monomer only in the photosensitive bottom layer that is in contact with the backing layer, but no silicone monomer in the photosensitive top layer that is in contact with a mask layer and taught to have a higher surface energy (e.g., at least 5 dynes/cm) than the bottom layer.

While the mask element precursors described in these publications have found considerable value in the flexographic industry, there is a need to further improve the process for making the mask elements in an efficient manner and to improve interlayer adhesion, intimate contact of mask element and relief-forming precursor during imaging when a lamination process is used, and a better draw-down of the mask element to the relief-forming precursor when vacuum draw-down is used.

Thus, there is a need for a technology that can be used for providing a photosensitive layer with a reduced surface energy and reduced peel force during removal of the mask.

### SUMMARY

In some embodiments, a relief-forming precursor can include a substrate and a relief-forming layer. The relief-forming layer can be prepared to have a bottom surface facing the substrate and a relief-forming surface facing away from the substrate. In some aspects, the relief-forming layer can include: a polymer, such as an elastomer; at least one photopolymerizable monomer; a photopolymerization initiator; and a low surface energy monomer. In some aspects, the low surface energy monomer has a silicone moiety linked (e.g., through a linker) to at least one polymerizable functional group. In some aspects, the at least one polymerizable functional group includes at least one type of acrylate moiety. In some aspects, the at least one type of acrylate moiety includes an acrylate or a methacrylate. In some aspects, the low surface energy monomer includes a plurality of polymerizable functional groups linked to the silicone moiety (e.g., silicone polymer, PDMS).

In some embodiments, the relief-forming precursor can include an adhesive layer on the substrate opposite of the relief-forming layer. In some aspects, an anti-halation material can be included in adhesive layer or omitted therefrom.

In some embodiments, the relief-forming precursor can consist essentially of in order: the substrate; an optional metal layer on the substrate; a single layer of the relief-forming layer on the substrate or metal layer; and an optional coversheet on the relief-forming layer.

In some embodiments, a relief-forming assembly can include a relief-forming precursor and a mask element. In some aspects, the relief-forming precursor can be configured with any of the embodiments described herein that includes the low surface energy monomer. In some aspects, the mask element can include an imaged layer with a mask image. In some aspects, the mask element can be in complete optical contact with the relief-forming surface of the relief-forming layer.

In some aspects, the relief-forming assembly can consist essentially of in order: the substrate; an optional metal layer on the substrate; a single layer of the relief-forming layer on the substrate or metal layer; and the mask element in complete optical contact with the relief-forming surface of the relief-forming layer.

In some embodiments, a method of making a relief-forming assembly can include: providing a mask element in accordance with an embodiment; providing a relief-forming layer that has a low surface energy monomer in accordance with an embodiment; placing an imaged layer of the mask element on a relief-forming surface of the relief-forming layer; and forming the complete optical contact between the mask element and the relief-forming surface. In some aspects, the method can include laminating the mask element to the relief-forming surface. In some aspects, the method can include vacuum drawdown coupling the mask element to the relief-forming surface.

In some embodiments, a method of making a relief image in a relief-forming assembly can include: providing a relief-forming assembly in accordance with an embodiment; exposing the relief-forming layer to curing UV radiation through the mask element to form an imaged relief-forming layer with UV-exposed regions forming polymerized regions and non-exposed regions forming non-polymerized regions in the imaged relief-forming layer; removing the mask element from the imaged relief-forming layer; and developing the imaged relief-forming layer by removing the non-polymerized regions in the imaged relief-forming layer, thereby forming a relief image element having a relief image (e.g., devoid of the non-polymerized regions. In some aspects, the method can include polymerizing the at least one photopolymerizable monomer and the low surface energy monomer with the photopolymerization initiator such that a low surface energy moiety is present in the body and at a relief surface of the relief image of the relief image element. In some aspects, the method can include polymerizing a plurality of polymerizable functional groups of the low surface energy monomer with the at least one photopolymerizable monomer so as to form a crosslinked polymer relief image element. In some aspects, the low surface energy monomer has a silicone moiety linked to at least one polymerizable functional group. In some aspects, the at least one polymerizable functional group includes at least one type of acrylate moiety.

In some embodiments, a relief-image element can include a substrate and a relief image layer. The relief image layer can have an elastomer and copolymer. The copolymer can include at least one photopolymerized monomer and a low surface energy monomer that has a silicone moiety. A relief surface of the relief image layer can have elevations and valleys of a relief image, and a portion of the silicone moiety is present at the relief surface. In some aspects, the copolymer includes a crosslinking of the photopolymerized monomer and low surface energy monomer.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE FIGURES

The foregoing and following information as well as other features of this disclosure will become more fully apparent from the following description and appended claims, taken in conjunction with the accompanying drawings. Understanding that these drawings depict only several embodiments in accordance with the disclosure and are, therefore, not to be considered limiting of its scope, the disclosure will be described with additional specificity and detail through use of the accompanying drawings.

FIG. 1A is a cross-sectional schematic illustration of an embodiment of a mask precursor according to the present invention, and showing incident infrared radiation useful for making a mask element.

FIG. 1B is a cross-sectional schematic illustration of an embodiment of a mask element formed from the mask precursor illustrated in FIG. 1A.

FIG. 1C is a cross-sectional schematic illustration of an embodiment of a relief image-forming assembly according to the present invention, comprising a mask element as illustrated in FIG. 1B that is in complete optical contact with a relief-forming precursor.

FIG. 1D is a cross-sectional schematic illustration of an embodiment of forming an imaged relief-forming precursor using incident UV radiation through the mask element illustrated in FIG. 1B.

FIG. 1E is a cross-sectional schematic illustration of an embodiment of a relief image element provided after imaging illustrated in FIG. 1D and suitable development process to remove non-exposed regions in the UV-sensitive layer of the imaged relief-forming precursor.

The elements and components in the figures can be arranged in accordance with at least one of the embodiments described herein, and which arrangement may be modified in accordance with the disclosure provided herein by one of ordinary skill in the art.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein, and illustrated in the figures, can be arranged, substituted, combined, separated, and designed in a wide variety of different configurations, all of which are explicitly contemplated herein.

Relief-Forming Precursor

Generally, the present technology includes a photosensitive relief-forming material that can be used in a relief-forming photopolymer plate precursor that has a low surface energy additive that results in a reduced surface energy and in a reduced peel force so that other layers, films, or bodies can be removed from the photosensitive relief-forming material without damaging any of these components. The resulting relief image element that still has the low surface energy additive, such as by being integrated (e.g., polymerized and/or crosslinked) with the matrix, has a reduced surface energy by the integrated low surface energy additive being present at the surface of the relief image. Particularly, the reduced peel force and reduced surface energy of the photosensitive relief forming layer allows for improved coupling with the mask and improved separation of the mask from the imaged relief-forming layer, such that the photosensitive relief-forming layer has improved properties that allow for improved use, imaging, and development. For example, the reduced surface energy from the low surface energy additive can reduce the surface energy of the material so that the mask layer can have a better and more complete optical coupling therewith, and then an improved separation. Also, the subsequent reduced surface energy allows improved use of the resulting photopolymer plate having the relief image element. The improved photosensitive relief-forming layer can also be used in solvent wash plates or water wash plates.

Considerable details of useful relief-forming precursors, such as flexographic printing plate precursors, letterpress printing plate precursors, and printed circuit boards are provided in U.S. '182 (noted above). Such relief-forming precursors can include a suitable dimensionally stable substrate and a relief-forming layer that is UV (ultraviolet)-sensitive, and optionally a coversheet and/or metal layer between substrate and relief-forming layer. Suitable substrates include dimensionally stable polymeric films and aluminum sheets. Polyester films are particularly useful. Any UV-sensitive material or element in which a relief image can be produced using a mask element is useful in the practice of this invention when it includes a low surface energy additive.

In some embodiments, relief-forming precursors generally include a suitable dimensionally stable substrate, a radiation curable layer having a low surface energy additive in which a flexographic relief image can be formed, and optionally a cover sheet on the radiation curable layer and/or metal layer between the substrate and radiation curable layer. Suitable substrates include flexible, dimensionally stable transparent polymeric films as well metal substrates, such as aluminum sheets. Polyester films are particularly useful as flexible, dimensionally stable, transparent substrates. The relief-forming precursor can optionally include a metal layer disposed between the substrate and the radiation curable layer. This metal layer can include copper or another metal or metal alloy.

Some embodiments also include a removable coversheet that protects the radiation curable layer from fingerprints and other damage and that is disposed on the radiation curable layer. In some embodiments, the flexographic printing plate precursor further comprises metal layer between the substrate and radiation curable layer, or both coversheet and metal layer sandwiching the radiation curable layer.

In some embodiments, the radiation curable layer can be a UV-sensitive layer that is cured by UV light. In some aspects, the UV-sensitive layer can be at least one layer of a relief-forming precursor that is formed by a relief-forming material that is UV-sensitive. Thus, references to the relief-forming material or layer refers to the UV-sensitive material or layer that can be irradiated with UV light and developed into a relief image.

In some embodiments, the relief-forming precursor includes: a backing or base film (e.g., as a substrate), a relief-forming layer (e.g., UV-sensitive material); and optionally a removable coversheet film to protect the photosensitive layer. In another option, a metal layer can be located between the substrate and the relief-forming layer.

In some embodiments, the backing or base can be configured to provide support to the relief-forming layer of the relief-forming precursor. The backing layer can be formed from transparent or opaque material such as paper, cellulose film, plastic, or metal. The backing layer is preferably formed from a transparent material that is flexible. Examples of such materials are cellulose films or plastics such as, PET (polyethylene terephthalate), PEN (polyethylene naphthalate), polyether, polyethylene, polyamide (Kevlar), or nylon. Preferably, the support layer is formed from polyethylene terephthalate (PET). It was also found that the relief-forming layer having the low surface energy additive was able to adhere to the support layer. The support layer can be from about 0.001 to about 0.010 inches thick. Optionally, various layers, such as an antihalation layer and/or an adhesive layer may be positioned between the backing layer and the relief-forming layer. In some aspects, the adhesive layer can include an antihalation material (e.g., light absorbing substance to prevent refraction of light) or may exclude such an antihalation material.

In some embodiments, the relief-forming layer with the reduced peel force can be a UV light photosensitive material that forms a relief image upon imaging with UV light and developing the image, where the relief image has reduced surface energy. The addition of the low surface energy additive to the UV light photosensitive material can provide a number of desirable properties to a relief image forming protocol, such as easier vacuum drawdown and better lamination to reduce bubble formation. Additionally, the reduced peel force allows for easier removal of the imaged mask from the relief-forming layer after the main UV exposure to form the relief image. Now, the protocol can be performed by peeling the mask from the imaged relief-forming layer. The improved separation from the reduced surface energy and reduced peel force can be applied to larger plate sizes, which are needed for commercial applications. Thus, the photosensitive relief-forming material having the reduced surface energy and reduced peel force provides easier separation of the mask element and photopolymer plate precursor assembly.

In some embodiments, the reduced surface energy and reduced peel force is obtained by incorporating a low surface energy additive into the composition of the photosensitive material. The low surface energy additive can be included within the matrix of the photosensitive material so as to be present and distributed within the body and on the surface of the photosensitive material. Often, the low surface energy additive is homogeneously mixed within the photosensitive material. However, the additive may be provided randomly or heterogeneously (e.g., non-homogeneously) or in gradients with increasing concentration preferentially to one side or the other.

In some embodiments, the low surface energy additive can include a silicone material, such as a silicone-based monomer having a reactive functional group. The reactive functional group can be selected to be polymerizable with the other polymerizable monomers of the photosensitive material. This allows the silicone to be incorporated into the polymerized material so that it is retained to the portion of the photosensitive material that remains after the relief forming process. As a result, the reactive functional group can be tailored from well-known functional groups that can participate in a polymerization reaction with specific types of other monomers that have the same functional groups or different but suitably reactive functional groups.

The low surface energy additive provides easer separation of the mask from the relief-forming precursor. It also provides a lower surface energy to the relief image layer of the flexographic printing plate which may provide additional benefit for printing.

In some embodiments, the silicone material of the low surface energy additive can include an acrylate functional group that can be reactive during polymerization. While acrylate (e.g., with hydrogen on the a carbon) may be used, other acrylates with substituents on the a carbon may also be used. The other acrylates can be substituted acrylates with the substituent being at the a carbon. A common example includes methacrylate that has the methyl on the a carbon. The silicone moiety can be attached to the oxygen of the ester of the acrylate moiety. The silicone moiety can include a linker to the oxygen of the ester.

In some embodiments, the silicone material can include a polydimethylsiloxane (PDMS) backbone with an alkyl or alkoxy side chain and with an acrylate group, such as acrylate or methacrylate. Such silicone acrylate additives are commercially available from various suppliers and may be referred to as a TEGO RAD (silicone polyether acrylate), such as TEGO RAD 2250, TEGO RAD 2300, TEGO RAD 2500, TEGO RAD 2700, CN9800 (difunctional aliphatic silicone acrylate oligomer), EBECRYL 350 (silicone di-acrylate) or the like.

In some embodiments, the silicon material can include the following structures of Formula 1 or Formula 2 or Formula 3 or Formula 4 or Formula 5:

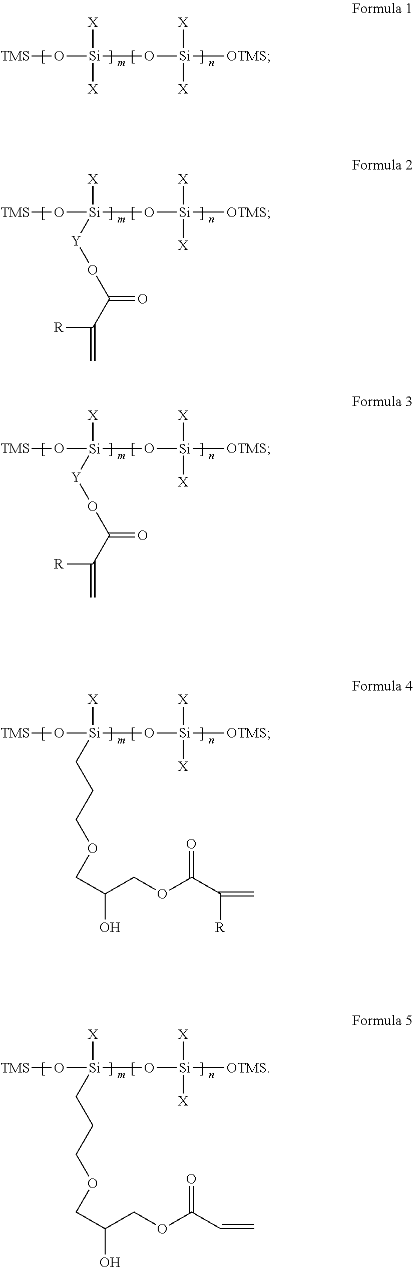

Formula 1 can include the m and n as defined below, and each X can independently be a substituent or a polymerizable functional group, wherein at least one X in the “m” monomer is a polymerizable functional group. In the formulae, the n ranges from 1 to 50 (or from 10 to 20 or from 14 to 16) and the m ranges from 0.1 to 10 (or 0.5 to 5 or 0.9 to 3 or 1 to 3), such as m being 1 for each monomer. The molecular weight can range from 1,000 g/mol to 2,500 g/mol. The Y can be any linker, such as those described herein or otherwise known in the art. For example, the Y can be the linker shown in Formula 4 and Formula 5. Also, the Y linker can include a C1-C10 alkyl, The R can be a substituent, such as an alkyl (e.g., methyl, ethyl, propyl, etc.).

In some embodiments, the Y linker can be a hydrocarbon chain with or without one or more hetero atoms, such as O, N, or S and with or without one or more substituents on the atoms of the chain. The Y linker may include straight aliphatics, branched aliphatics, cyclic aliphatics, substituted aliphatics, unsubstituted aliphatics, saturated aliphatics, unsaturated aliphatics, aromatics, polyaromatics, substituted aromatics, hetero-aromatics, ethers, amines, primary amines, secondary amines, tertiary amines, aliphatic amines, carbonyls, carboxyls, amides, esters, amino acids, peptides, polypeptides, derivatives thereof, substituted or unsubstituted, with or without hetero atoms, or combinations. In some aspects, the Y linker can include C1-C24 alkyl, C2-C24 alkenyl, C2-C24 alkynyl, C1-C24 alkyl esters, C6-C20 aryl, C7-C24 alkaryl, C7-C24 aralkyl, amino, mono- and di-(alkyl)-substituted amino, mono- and di-(aryl)-substituted amino, alkylamido, arylamido, imino, alkylimino, arylimino, nitro, nitroso, sulfo, sulfonato, alkylsulfanyl, arylsulfanyl, alkylsulfinyl, arylsulfinyl, alkyl sulfonyl, arylsulfonyl, phosphono, phosphonato, phosphinato, phospho, phosphino, any with or without hetero atoms, any with or without a substituent, derivatives thereof, and combinations thereof.

In some embodiments, the substituent X or substituent on the linker can be a common substituent, such as hydrogen, alkyl, alkenyl, alkynyl, alkyl ester, aryl, alkaryl, aralkyl, halo, hydroxyl, sulfhydryl, alkoxy, alkenyloxy, alkynyloxy, aryloxy, acyl, alkylcarbonyl, arylcarbonyl, acyloxy, alkoxycarbonyl, aryloxycarbonyl, halocarbonyl, alkylcarbonato, arylcarbonato, carboxy, carboxylato, carbamoyl, mono-(alkyl)-substituted carbamoyl, di-(alkyl)-substituted carbamoyl, mono-substituted arylcarbamoyl, thiocarbamoyl, carbamido, cyano, isocyano, cyanato, isocyanato, isothiocyanato, azido, formyl, thioformyl, amino, mono- and di-(alkyl)-substituted amino, mono- and di-(aryl)-substituted amino, alkylamido, arylamido, imino, alkylimino, arylimino, nitro, nitroso, sulfo, sulfonato, alkylsulfanyl, arylsulfanyl, alkylsulfinyl, arylsulfinyl, alkyl sulfonyl, arylsulfonyl, phosphono, phosphonato, phosphinato, phospho, phosphino, any with or without hetero atoms, any including straight chains, any including branches, and any including rings, derivatives thereof, and combinations thereof. For example, Formulae 4 and 5 show an alkyl ester linker that is substituted with a hydroxyl.

For Formulae 2-5: when m is 1, the silicone monomer is monofunctional; when m is 2, the silicone monomer is di-functional; when, the m is 3, the monomer is tri-functional, and so on. Thus, the monomer may be multi-functional, which allows for crosslinking during the polymerization, such as when m is 2 or more. Formula 1 can be monofunctional when only one X is a polymerizable functional group, and m is 1, but may be multi-functional in other scenarios.

In some embodiments, the silicone moiety can be a mono-acrylate, di-acrylate, tri-acrylate, or other multi-acrylate. Di-acrylates and above can be involved in crosslinking with the polymerizable monomers. As a result, the polymerization can result in crosslinking by using the silicone multi-acrylate monomer as the low surface energy additive. Thus, the formation of the imaged UV-sensitive material can include crosslinking the monomers with the silicon multi-acrylate monomer

In some embodiments, the low surface energy additive is not a silicone oil. That is, the low surface energy additive is not a silicone that is free within the material. Instead, embodiments include the low surface energy additive having the reactive functional group that can participate in polymerization so that the silicone is covalently coupled to the polymerized material. In some aspects, the low surface energy additive is polymerized upon exposure to the UV curing radiation. For example, the silicone acrylate or silicone methacrylate can be used. Thus, the low surface energy additive includes a functional group for polymerization and linking to the polymerized matrix and includes the silicone for reducing surface energy and reducing peel force of the UV-sensitive layer. The incorporation into the binder inhibits the silicone from migration, which migration can be a problem with silicone oil. Thus, the silicone oil or other silicone without a polymerizable functional group is omitted from the present invention in some embodiments.

In some embodiments, the relief-forming precursor can include only a single body or single layer of the UV-sensitive material. That is, the substrate of the relief-forming precursor can include only a single layer of the UV-sensitive material having the low surface energy additive. As such, the UV-sensitive material is the top layer when ready to be combined with the mask, and the same UV-sensitive material is the only UV-sensitive material in the relief-forming precursor. A second UV-sensitive layer, whether adjacent or separate, is omitted from the relief-forming precursor described herein. Thus, the totality of the UV-sensitive layer includes the low surface energy additive.

In some embodiments, the low surface energy additive, such as the silicone acrylate, can be included in the UV-sensitive material in an amount ranging from about 0.1% to about 5% by weight of the material, or ranging from about 0.2% to about 4% by weight, about 0.3% to about 3% by weight, or ranging from about 0.4% to about 2% by weight, or ranging from about 0.5% to about 1%, or any range of the recited endpoints, such as 0.5% to about 2%, etc.

In some embodiments, the low surface energy additive can be distributed throughout the matrix. In some aspects, the low surface energy additive may be added to a top surface of the UV-sensitive material.

The photosensitive layer having the low surface energy additive can be in a relief-forming precursor that is positive- or negative-working, but typically, it is negative-working, and generally includes a UV-sensitive layer (or photocurable or relief-image forming layer or photosensitive layer, etc.) containing a UV-radiation curable composition that is cured or hardened by polymerization or crosslinking upon exposure to the curing UV radiation. Many details of various components of the UV-sensitive relief-forming precursors are provided in U.S. '182 (noted above) and references cited therein.

Some embodiments of relief-forming precursors can include a removable coversheet on the photosensitive layer that has the reduced surface energy and reduced peel force. The reduced surface energy and reduced peel force facilitates removal of the coversheet.

In some embodiments, the photosensitive material that has reduced surface energy and reduced peel force can be a UV-sensitive layer that includes: an elastomeric binder; at least one polymerizable or photocurable monomer; a photopolymerizing photoinitiator that is sensitive to UV radiation; and a low surface energy monomer, such as the polymerizable silicone material described herein. Suitable photoinitiator compositions include but are not limited to those described in U.S. Pat. No. 4,323,637 (Chen et al.), U.S. Pat. No. 4,427,749 (Graetzel et al.), and U.S. Pat. No. 4,894,315 (Feinberg et al.). The low surface energy monomer can be added to the photoinitiator compositions to form the photosensitive material with reduced surface energy and reduced peel force.

The elastomeric binder can include more polymers or resins that can be soluble, swellable, or dispersible in aqueous, semi-aqueous, or organic solvent developers (described below) and can include but are not limited to, natural or synthetic polymers of conjugated diolefins, block copolymers, core-shell microgels, and blends of microgels and preformed macromolecular polymers. The elastomeric binder can comprise at least 65 weight % and up to and including 90 weight %, based on total dry UV-sensitive layer weight.

In some embodiments, the elastomeric binder may be a single polymer or mixture of polymers (e.g., homopolymers, copolymers, random copolymers, block copolymers, any with any number of different types of monomers) which may be soluble, swellable or dispersible in aqueous, semi-aqueous or organic solvent developers. Suitable binders include those described in, U.S. Pat. No. 3,458,311 (Alles), U.S. Pat. No. 4,442,302 (Pohl), U.S. Pat. No. 4,361,640 (Pine), U.S. Pat. No. 3,794,494 (Inoue), U.S. Pat. No. 4,177,074 (Proskow), U.S. Pat. No. 4,431,723 (Proskow), and U.S. Pat. No. 4,517,279 (Worns). Binders which are soluble, swellable or dispersible in organic solvent developers include natural or synthetic polymers of conjugated diolefin hydrocarbons, including polyisoprene, 1,2-polybutadiene, 1,4-polybutadiene, butadiene/acrylonitrile, butadiene/styrene thermoplastic-elastomeric block copolymers and other copolymers. The block copolymers discussed in U.S. Pat. No. 4,323,636 (Chen), U.S. Pat. No. 4,430,417 (Heinz), and U.S. Pat. No. 4,045,231 (Toda) may be used. The elastomeric binder may be present in an amount of at least about 65% by weight of the photosensitive material. The term binder, as used herein, encompasses core-shell microgels and blends of microgels and preformed macromolecular polymers, such as those described in U.S. Pat. No. 4,956,252 (Fryd).

The at least one polymerizable monomer can be configured to be compatible with the elastomeric binder to the extent that a clear, non-cloudy UV-sensitive imageable layer is produced. Polymerizable monomers for this purpose are well known the art and include ethylenically unsaturated polymerizable compounds having relatively low molecular weight (generally less than 30,000 Daltons). Suitable monomers have a relatively low molecular weight, less than about 5000 Da. Unless described otherwise, throughout the specification molecular weight is the weight-average molecular weight. Examples of suitable polymerizable monomers include various mono- and polyacrylates, acrylate derivatives of isocyanates, esters, and epoxides. Additionally, examples of suitable monomers include t-butyl acrylate, lauryl acrylate, the acrylate and methacrylate mono- and polyesters of alcohols and polyols such as alkanols, e.g., 1,4-butanediol diacrylate, 2,2,4-trimethyl-1,3 pentanediol dimethacrylate, and 2,2-dimethylolpropane diacrylate, alkylene glycols, e.g., tripropylene glycol diacrylate, butylene glycol dimethacrylate, hexamethylene glycol diacrylate, and hexamethylene glycol dimethacrylate, trimethylol propane, ethoxylated trimethylol propane, pentaerythritol, e.g., pentaerythritol triacrylate, dipentaerythritol, and the like. Other examples of suitable monomers include acrylate and methacrylate derivatives of isocyanates, esters, epoxides and the like, such as decamethylene glycol diacrylate, 2,2-di(p-hydroxyphenyl)propane diacrylate, 2,2-di(p-hydroxyphenyl)propane dimethacrylate, polyoxyethyl-2,2-di(p-hydroxyphenyl)propane dimethacrylate, and 1-phenyl ethylene-1,2-dimethacrylate. Further examples of monomers can be found in U.S. Pat. No. 4,323,636 (Chen), U.S. Pat. No. 4,753,865 (Fryd), U.S. Pat. No. 4,726,877 (Fryd), and U.S. Pat. No. 4,894,315 (Feinberg). The monomer may comprise at least 5% by weight to about 25% by weight of the photosensitive material, which can be based on total dry weight of the photosensitive material.

The photoinitiator may be any single compound or combination of compounds sensitive to ultraviolet radiation, generating free radicals which initiate the polymerization of the monomer or monomers without excessive termination. The photoinitiator can be sensitive to visible or ultraviolet radiation. The photoinitiator may also be insensitive to infrared and/or visible radiation and can be thermally inactive at and below 185° C. Examples of suitable photoinitiators include the substituted and unsubstituted polynuclear quinones. Examples of suitable systems have been disclosed in U.S. Pat. No. 4,460,675 (Gruetzmacher) and U.S. Pat. No. 4,894,315 (Feinberg). Photoinitiators are generally present in amounts from 0.001% to 10.0% by weight based on the weight of the photosensitive material.

In some embodiments, the photosensitive layer can include: a di- or tri-block co-polymer (e.g., elastomer); at least one photopolymerizable monomer; photopolymerization initiator; plasticizer; additives such as stabilizers, inhibitors, colorants, solvents; and the low surface energy monomer, such as, a silicone acrylate or silicone methacrylate.

In some embodiments, the plasticizer can be any suitable plasticizer known in the art of photosensitive layers for use as described herein. Examples of suitable plasticizers include aliphatic hydrocarbon oils, e.g., naphthenic and paraffinic oils, liquid polydienes, e.g., liquid polybutadiene, liquid polyisoprene. Generally, plasticizers are liquids having molecular weights of less than about 5,000 Da, but can have molecular weights up to about 30,000 Da. Plasticizers having low molecular weight will encompass molecular weights less than about 30,000 Da.

In some embodiments, the additives can include rheology modifiers, thermal polymerization inhibitors, stabilizers, inhibitors, tackifiers, colorants, antioxidants, antiozonants, solvents, or fillers. These materials are commonly used in photosensitive layers and examples can be provided in the incorporated references.

The thickness of the photosensitive layer may vary depending upon the type of printing plate desired. In one embodiment, the photosensitive layer may be, for example, from about 20-250 mils (500-6,400 microns) or greater in thickness, more particularly from about 20-100 mils (500-2,500 microns) in thickness.

In some embodiments, the relief-forming precursor is a flexographic printing plate precursor that includes a suitable UV-curable composition (e.g., photosensitive material) in the UV-sensitive layer (e.g., photosensitive layer) that when exposed through the mask element and developed, provides a relief image in a flexographic printing plate. Such relief-forming precursors generally include a suitable substrate with the photosensitive material. Examples of commercially available flexographic printing plate precursors include but are not limited to, FLEXCEL NX flexographic elements available from Miraclon Corporation, CYREL® Flexographic plates available from DuPont (Wilmington, Del.), NYLOFLEX® FAR 284 plates available from BASF (Germany), FLEXILIGHT CBU plate available from Macdermid (Denver, Co.), and ASAHI AFP XDI available from Asahi Kasei (Japan). These flexographic printing plate precursors can be modified to include the low surface energy monomer as described herein.

In some embodiments, the relief-forming precursor can also be used to form a printed circuit board wherein a conducting layer (also known as a “printing circuit”) is formed on a substrate in the pattern dictated by exposure through a mask element. Suitable precursors to printed circuit boards generally comprise a substrate, a metal layer, and a UV-sensitive imageable layer (e.g., photosensitive material). Suitable substrates include but are not limited to, polyimide films, glass-filled epoxy or phenol-formaldehyde or any other insulating materials known in the art. The metal layer covering the substrate is generally a conductive metal such as copper or an alloy or metals. The UV-sensitive imageable layer can include an UV-curable resin, polymerizable monomers, or oligomers, photoinitiators, and a polymeric binder. Further details of printed circuit boards are provided in U.S. '182 (noted above).

Mask and Mask Precursor

A mask for use with the relief-forming precursor with the photosensitive layer having the low surface energy additive can be prepared from a mask precursor. The mask precursor can be prepared and processed with light (e.g., infrared, IR) to form a mask. The mask can then be combined with the relief-forming precursor (e.g., by lamination) and processed and then the mask and relief-forming precursor that is processed with light are separated from each other. During the separation process, it is important for the relief-forming layer is not damaged. As such, the low surface energy additive in the relief-forming layer of the relief-forming precursor can facilitate easier separation (e.g., delamination) of the mask from the imaged relief-forming layer of the relief-forming precursor.

The mask precursor can be considered an imageable material due to having an imageable layer that forms the mask. The mask precursor can include three essential layers or films as described below, in order: a (a) transparent polymeric carrier sheet; a (b) a light to heat converting (LTHC) layer; and a (c) non-silver halide thermally-ablatable imaging layer (IL). Here, the LTHC layer is non-ablatable by thermal imaging with light, such as IR light. The non-silver halide thermally-ablatable imaging layer is ablatable by thermal imaging with light, such as IR light, but this thermally-ablatable imaging layer does not include a silver halide, and thereby is “a non-silver halide” imaging layer that is thermally ablatable. Accordingly, the LTHC layer includes substances that are not ablatable by thermal energy during imaging the IL layer with IR light. On the other hand, the IL layer includes substances that are thermally ablatable. Only these three layers or films are essential for forming a mask element (e.g., referred to as a mask) having a mask image in the IL layer. However, as noted below, in some embodiments, a (d) transparent polymeric overcoat layer can be disposed directly on the IL, but this optional feature is not required for forming a mask or using a mask image. Rather, it can be helpful in some uses for providing abrasion resistance.

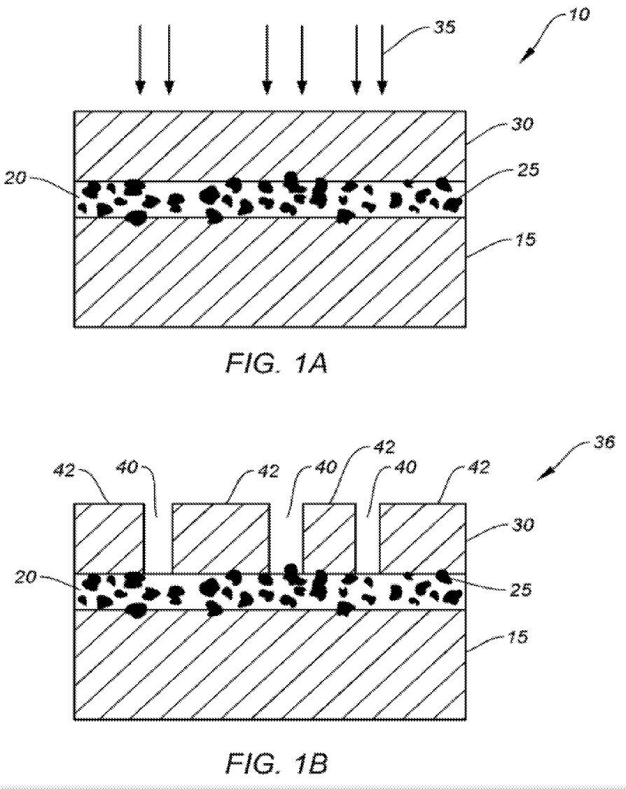

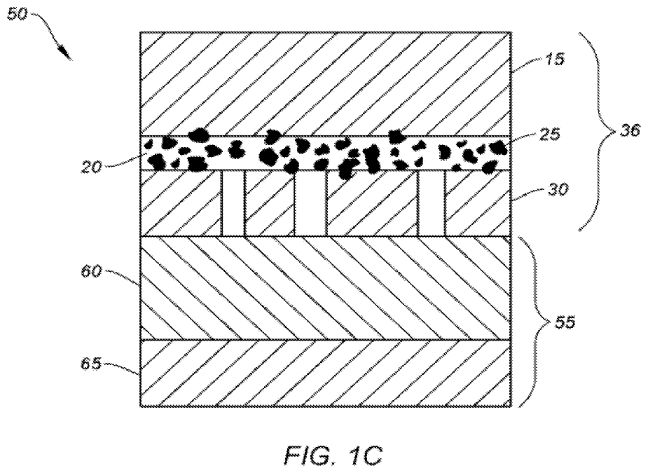

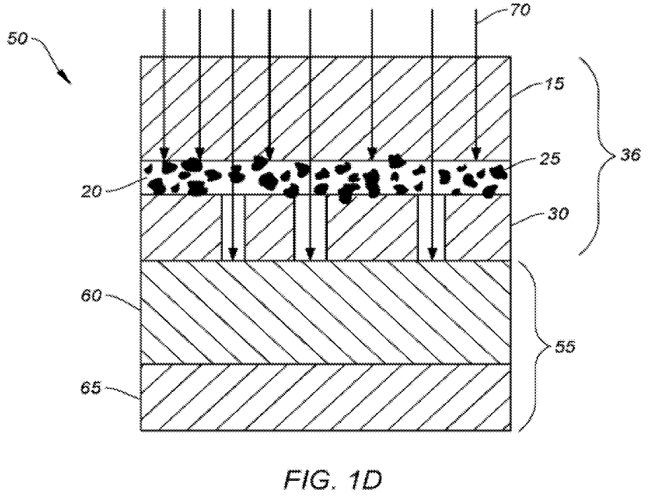

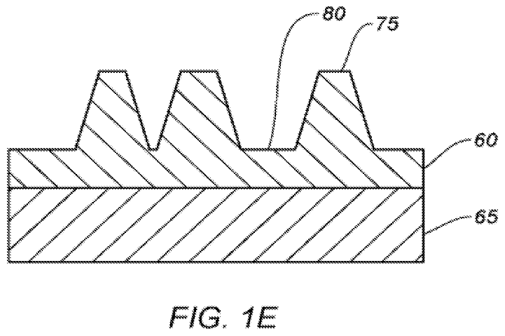

The mask precursor that is used to form a mask element that is used eventually to form a relief image can be prepared and then processed into the mask as described herein. In some embodiments, the mask precursor 10 is illustrated in FIG. 1A, which has (a) transparent polymeric carrier sheet 15, on which is directly disposed (b) LTHC layer 20 containing a non-ablatable binder material having the non-ablatable particles 25 that are described in more detail below, and (c) an ablatable IL 30 that is disposed directly on LTHC layer 20 and positioned to receive the light 35 shown by the arrows.

Transparent Polymeric Carrier Sheet

The transparent polymeric carrier sheet can be any suitable transparent substrate or film. Useful transparent polymeric carrier sheets can be but are not limited to, transparent polymeric films and sheets composed of one or more polymers, such as polyesters including poly(ethylene terephthalate), poly(ethylene naphthalate), and fluorine polyester polymers; polyethylene-polypropylene copolymers; polybutadienes; polycarbonates; polyacrylates (polymers formed at least in part from one or more (meth)acrylate ethylenically unsaturated monomers); vinyl chloride polymers such as polyvinyl chloride and copolymers derived at least in part from vinyl chloride; hydrolyzed or non-hydrolyzed cellulose acetates; and other materials that would be readily apparent to one skilled in the art. The transparent polymeric carrier sheets can be composed of two or more polymeric materials as a blend or composite as long as the requisite transparency and protective properties are achieved. They can be formed as a single polymeric film or laminate of multiple polymeric films. Generally, the transparent polymeric carrier sheet has an average dry thickness of at least 25 μm and up to and including 250 or typically of at least 75 μm and up to and including 175 μm.

For example, a transparent poly(ethylene terephthalate) sheet that is available from various commercial sources is suitable as a transparent polymeric carrier sheet.

If necessary, the transparent polymeric carrier sheet surface can be treated to modify its wettability and adhesion to applied coatings (such as an LTHC layer coating). Such surface treatments include but are not limited to corona discharge treatment and the application of subbing layers as long as the desired transparency (described above) is achieved.

If desired, the transparent polymeric carrier sheet can also comprise one or more “first” ultraviolet radiation absorbing compounds (as described below for the LTHC layer or IL). The one or more compounds of this type can be the same or different as the ultraviolet radiation absorbing compounds in the IL (see below). Each useful ultraviolet radiation absorbing compound generally absorbs electromagnetic radiation of at least 150 nm and up to and including 450 nm. These compounds can be present in the transparent polymeric carrier sheet in an amount of at least 0.01 weight % and up to and including 0.1 weight %, based on the total dry weight of the transparent polymeric carrier sheet.

In addition, the transparent polymeric carrier sheet can contain one or more “adhesion promoters” that improve adhesion between it and the adjacent LTHC layer. Useful adhesion promoters include but are not limited to, gelatin, poly(vinylidene chloride), poly (acrylonitrile-co-vinylidene chloride-co-acrylic acid), and polyethyleneimine.

Non-Ablatable Light-to-Heat Converting (LTHC) Layer

The mask precursor also includes the non-ablatable LTHC layer disposed on the transparent polymeric carrier sheet and directly between the transparent polymeric carrier sheet and the IL. Suitable LTHC layer compositions have three essential components: a (i) first infrared radiation absorbing material; a (ii) a non-ablatable crosslinked binder material that is a thermally crosslinked organic polymer that is not ablatable by light radiation, such as IR radiation, visible radiation, or UV radiation; and (iii) non-ablatable particles that are not ablatable by light radiation, such as IR radiation, visible radiation, or UV radiation. The LTHC layer is generally disposed as a relatively uniform coating on the transparent polymeric carrier sheet (that is, being substantially continuous and having fairly uniform wet thickness) and then dried if any solvent is present in the composition formulation.

The LTHC layer is generally transparent as that term is defined above. In particular, the LTHC layer is transparent to UV radiation used to image the relief-forming precursor, as defined below.

One or more infrared absorbing materials that are collectively identified herein as the “first” infrared radiation absorbing material to distinguish it, if necessary, from the second infrared radiation absorbing material(s) in the IL (described below). The first infrared radiation absorbing material may also be in the transparent polymeric carrier sheet. The first and second infrared radiation absorbing materials can be one or more dyes or pigments, or mixtures thereof that will provide desired spectral absorption properties and are independently sensitive to electromagnetic radiation in the infrared electromagnetic wavelength range of at least 700 nm and up to and including 1,500 nm and typically of at least 750 nm and up to and including 1,200 nm. Such materials can be particulate in nature and are dispersed within the (ii) non-ablatable crosslinked binder material(s) described below. For example, they can be black dyes or pigments such as carbon black, metal oxides, and other materials described for example in U.S. '182 (noted above).

One suitable IR-absorbing pigment is a carbon black of which there are numerous types with various particles sizes that are commercially available. Examples include RAVEN 450, 760 ULTRA, 890, 1020, 1250 and others that are available from Columbian Chemicals Co. (Atlanta, Ga.) as well as BLACK PEARLS 170, BLACK PEARLS 480, VULCAN XC72, BLACK PEARLS 1100 and others available from Cabot Corporation. Other useful carbon blacks are surface-functionalized with solubilizing groups. Carbon blacks that are grafted to hydrophilic, nonionic polymers, such as FX-GE-003 (manufactured by Nippon Shokubai), or which are surface-functionalized with anionic groups, such as CAB-0-JET® 200 or CAB-O-JET® 300 (manufactured by the Cabot Corporation) are also useful.

Useful first infrared radiation absorbing materials also include IR dyes including but not limited to, cationic infrared-absorbing dyes and photothermal-bleachable dyes. Examples of suitable IR dyes include but are not limited to, azo dyes, squarilium dyes, croconate dyes, triarylamine dyes, thiazolium dyes, indolium dyes, oxonol dyes, oxazolium dyes, cyanine dyes, merocyanine dyes, phthalocyanine dyes, indocyanine dyes, indotricarbocyanine dyes, oxatricarbocyanine dyes, thiocyanine dyes, thiatricarbocyanine dyes, merocyanine dyes, cryptocyanine dyes, naphthalocyanine dyes, polyaniline dyes, polypyrrole dyes, polythiophene dyes, chalcogenopyryloarylidene and bi(chalcogenopyrylo) polymethine dyes, oxyindolizine dyes, pyrylium dyes, pyrazoline azo dyes, oxazine dyes, naphthoquinone dyes, anthraquinone dyes, quinoneimine dyes, methine dyes, arylmethine dyes, squarine dyes, oxazole dyes, croconine dyes, porphyrin dyes, and any substituted or ionic form of the preceding dye classes. Suitable dyes are also described in U.S. Pat. No. 5,208,135 (Patel et al.), U.S. Pat. No. 6,569,603 (Furukawa), and U.S. Pat. No. 6,787,281 (Tao et al.), and EP Publication 1,182,033 (Fijimaki et al.). A general description of one class of suitable cyanine dyes is shown by the formula in paragraph [0026] of WO 2004/101280.

Near infrared absorbing cyanine dyes are also useful and are described for example in U.S. Pat. No. 6,309,792 (Hauck et al.), U.S. Pat. No. 6,264,920 (Achilefu et al.), U.S. Pat. No. 6,153,356 (Urano et al.), U.S. Pat. No. 5,496,903 (Watanate et al.), the disclosures of all of which are incorporated herein by reference. Suitable dyes may be formed using conventional methods and starting materials or obtained from various commercial sources including American Dye Source (Baie D'Urfe, Quebec, Canada) and FEW Chemicals (Germany).

The first infrared radiation absorbing material(s) is generally present in an amount sufficient to provide a transmission optical density of at least 0.025 and typically of at least 0.05 at the exposing electromagnetic radiation wavelength (e.g., IR). Generally, this is achieved by including at least 0.1 weight % and up to and including 5 weight %, or typically at least 0.3 weight % and up to and including 3 weight %, based on the total dry weight of the LTHC layer.

The first infrared radiation absorbing material in the LTHC layer can be the same or different chemical material(s) as the second infrared radiation absorbing compound that is incorporated into the IL as described below. The infrared radiation absorbing material in the LTHC layer may also be different from the infrared radiation absorbing material in the transparent polymeric carrier. In most embodiments, the first and second infrared radiation absorbing materials are the same chemical materials. The amounts of the first and second infrared radiation absorbing materials in the imageable material can be the same or different. In most embodiments, they are present in different amounts in the imageable material.

As noted, the LTHC layer comprises a non-ablatable crosslinked binder formed from one or more thermally crosslinked organic polymeric binders derived from thermally crosslinkable organic polymeric binders that have been crosslinked. The term “thermally crosslinkable” means that crosslinking groups are present and include for example, hydroxy-containing polymers. Particularly useful thermally crosslinkable organic polymers include but are not limited to, crosslinkable nitrocellulose; crosslinkable polyesters such as polyesters containing hydroxy groups; polyvinyl alcohol's; polyvinyl acetals such as polyvinyl butyral; or a combination of two or more of such crosslinkable organic polymeric materials. The corresponding non-ablatable crosslinked binder material can be obtained by crosslinking the noted thermally crosslinkable organic polymeric materials.

The non-ablatable crosslinked binder material formed from thermally crosslinked organic polymers can be present in the LTHC layer in an amount of at least 40 weight % and up to and including 90 weight %, or more likely in an amount of at least 50 weight % and up to and including 80 weight %, all based on total dry weight of the LTHC layer.

A third essential component of the LTHC layer are the non-ablatable particles, which are not ablatable by light radiation or resulting thermal heat from light radiation, and thereby the non-ablatable particles are considered to be non-thermally-ablatable particles. The non-thermally-ablatable particles are defined to be not thermally ablative under exposure to the light radiation during formation of the mask or formation of the relief image. The non-ablatable particles can include an average particle size of at least 0.1 μm and up to and including 20 μm, or at least 5 μm and up to and including 15 μm. The term “average” is used here to refer to measurements of particle size of the dispersed particles and can be determined from either a manufacturer's specification or by measuring at least 10 different particles and taking an average.

The term “non-ablatable” with regard to the non-ablatable particles is used here to mean that the particles are not sensitive to the laser imaging wavelength and intensity compared to materials that are strongly affected by the laser imaging ablation process of forming the mask. Also, the particles are not sensitive to UV radiation during formation of the relief image from the mask and the relief-forming precursor. Materials that are sensitive to the laser thermal imaging ablation process have strong absorption to the laser wavelength of the imaging laser and have low thermal decomposition temperatures so that they are ablative, and such materials are not used in the non-ablatable particles.

Conversely, non-ablative particles used in the present invention are not strongly absorbing of the laser imaging wavelength and do not have very low thermal decomposition temperatures. Some of the non-thermally-ablatable particles can protrude out of the LTHC layer, for example, into the IL, but are retained in the LTHC layer or at least partially embedded therein.

The non-ablatable particles useful in the LTHC layer include but are not limited to, particles of silica, titanium dioxide, zinc oxide, or a combination of two or more types of such particles. Silica particles are particularly useful in the practice of this invention. Moreover, such non-ablatable particles can be present in the LTHC layer in an amount of at least 0.2 weight % and up to and including 10 weight %, or at least 1 weight % and up to and including 7 weight %, all based on the total dry weight of the LTHC layer.

Optionally, during formation the LTHC layer can comprise one or more thermal crosslinking agents to provide improved handling of the mask element. Such optional thermal crosslinking agents facilitate crosslinking of the thermally crosslinkable organic binder polymers during coating and drying of the LTHC layer to form the non-ablatable crosslinked binder. Heat can be used for drying during formation of the mask element. The thermal crosslinking agent(s) can be present in an amount of at least 5 weight % and up to and including 25 weight %, based on the total dry weight of the crosslinkable polymer that is crosslinked into the non-ablatable LTHC layer. Such materials can include but are not limited to, melamine-formaldehyde resins, dialdehydes, phenolics, polyfunctional aziridines, isocyanates including polyisocyanates, and urea-formaldehyde epoxies. However, the formed LTHC layer is a crosslinked binder so crosslinking agents can be all used or not present or only present in small amounts in the formed crosslinked material that is non-ablative.

The LTHC layer generally has an average dry thickness of at least 1 μm and up to and including 5 μm or typically at least 1 μm and up to and including 3 μm.

Non-Silver Halide Thermally-Ablatable Imaging Layer (IL)

The IL that is incorporated into the mask precursor is generally disposed directly on the LTHC layer as a relatively uniform coating (that is, being substantially continuous and having fairly uniform wet thickness) and then dried if any solvent is present in the formulation. In most embodiments, IL is a single coated or applied layer, but in other embodiments, there can be multiple sub-layers or sub-coatings making up the IL disposed directly on the LTHC layer described above.

As stated in the terminology, there is essentially no silver halide present in the IL. In other words, no silver halide is purposely added or created in the IL.

The IL generally includes one or more ultraviolet radiation absorbing materials (UV-light absorbing materials) as an essential component. These compounds generally have an absorbance of at least 1.5 and up to and including 5 in an electromagnetic radiation wavelength range of at least 300 nm and up to and including 450 nm. In general, useful ultraviolet radiation absorbing materials include but are not limited to benzotriazoles, halogenated benzotriazoles, triazines, benzophenones, benzoates, salicylates, substituted acrylonitriles, cyanoacrylates, benzilidene malonates, oxalanilides, and mixtures thereof. Examples of useful ultraviolet radiation absorbing materials include but are not limited to, UV absorbing dyes or UV stabilizers marketed under the names Uvinul® (BASF), Keyplast® (Keystone Aniline Corporation), Sanduvor® (Sandoz Chemicals Corp.), Hostavin (Clariant), and Tinuvin® (BASF or Ciba). Examples of useful materials are described in U.S. Pat. No. 5,496,685 (Farber et al.).

The one or more ultraviolet radiation absorbing compounds can be present in the IL in an amount of at least 10 weight % and up to and including 40 weight %, or typically at least 15 weight % and up to and including 30 weight %, based on the total dry weight of the IL.

The IL also comprises one or more second infrared radiation absorbing materials as a second essential component, which second infrared radiation absorbing materials are defined like the first infrared radiation absorbing materials described above for the LTHC layer, and they can be the same or different as the first infrared radiation absorbing materials. The one or more second infrared radiation absorbing materials can be present in the IL in an amount sufficient to provide a transmission optical density of at least 0.5 and typically of at least 0.75 at the exposing wavelength. Generally, this is achieved by including at least 3 weight % and up to and including 20 weight % of the one or more second infrared radiation sensitive compounds, based on the total dry weight of the IL.

The IL can optionally include one or more fluorocarbon additives for improved production of halftone dots (that is, pixels) having well-defined, generally continuous, and relatively sharp edges. Examples of useful fluorocarbon additives and amounts are provided in [0087] to [0089] of U.S. '182 (noted above).

Additional optional components of the IL include but are not limited to, plasticizers, coating aids or surfactants, dispersing aids, fillers, and colorants, all of which are well known in the art as described for example in [0094] to [0096] of U.S. '182 (noted above). For example, the IL further can comprise one or more fluorocarbon additives or one or more non-thermally ablatable colorants.

All the essential and optional components described above for the IL are dispersed in one or more ablatable polymeric binder materials that include both synthetic and naturally occurring polymeric materials that are ablatable when exposed to light radiation, such as such as IR radiation, visible radiation, or UV radiation. In some aspects, the ablatable polymeric binder in the IL is not crosslinked, and thereby is a non-crosslinked binder. Such materials are capable of dissolving or dispersing the essential and optional components in a uniform manner throughout the IL. The one or more ablatable polymeric binder materials can be present in an amount of at least 25 weight % and up to and including 75 weight %, or typically of at least 35 weight % and up to and including 65 weight %, based on the total dry weight of the IL.

Useful ablatable polymeric binder materials include but are not limited to, the materials described for example in [0081] to [0085] of US '182. These materials can also be known as “adhesive binders” as described for example in [0081] of U.S. '182.

Examples of such materials include but are not limited to, acetyl polymers such as poly(vinyl butyral)s that can be obtained for example as BUTVAR® B-76 from Solution, Inc. (St. Louis, Mo.) and acrylamide polymers that can be obtained as MACROMELT 6900 from Henkel Corp. (Gulph Mills, Pa.). Pressure-sensitive adhesive polymers can also be used for this purpose.

In some embodiments, it is advantageous to use binder materials in the IL that are easily thermally-combustible or thermally-ablatable, and that generate gases and volatile fragments at temperature less than 200° C. Examples of these materials are thermally ablatable nitrocellulose, polycarbonates, poly(cyanoacrylate)s, polyurethanes, polyesters, polyorthoesters, polyacetals, and copolymers thereof (see for example, U.S. Pat. No. 5,171,650 of Ellis et al., Col. 9, lines 41-50, the disclosure of which is incorporated herein by reference), which can be non-crosslinked.

Other useful ablatable materials for the IL have hydroxyl groups (or hydroxylic polymers) as described in [0082] to [0084] of U.S. '182 (noted above) such as poly(vinyl alcohol)s and cellulosic polymers (such as nitrocellulose). Still other useful polymers are non-crosslinkable polyesters, polyamides, polycarbamates, polyolefins, polystyrenes, polyethers, polyvinyl ethers, polyvinyl esters, and polyacrylates and polymethacrylates having alkyl groups with 1 and 2 carbon atoms.

Particularly useful abatable materials for the IL include but are not limited to, a polyurethane, poly(vinyl butyral), (meth)acrylamide polymer, nitrocellulose, polyacetal, poly(cyanoacrylate), a polymer derived at least in part from any of methyl methacrylate, ethyl methacrylate, n-butyl methacrylate, and isobutyl methacrylate, or a combination of two or more of these materials.

The IL can have an average dry thickness of at least 0.5 μm and up to and including 5 μm or typically of at least 0.8 μm and up to and including 2.5 μm.

Transparent Polymeric Overcoat Layer

In some embodiments, the mask precursor optionally includes a transparent polymeric overcoat layer that is disposed directly on the IL opposite of the LTHC layer. Although such a transparent polymeric overcoat layer is not essential to the advantages of the present invention. The transparent polymeric overcoat layer generally includes one or more transparent film-forming polymers or resins including but not limited to, a methacrylic acid copolymer (such as a copolymer of ethyl methacrylate and methacrylic acid) and particles of one or more fluoropolymers dispersed therein as described, for example, in U.S. Pat. No. 6,259,465 (Tutt et al.) the disclosure of which is incorporated herein by reference. The transparent polymeric overcoat layer can provide abrasion resistance during handling due to the presence of the fluoropolymer particulates. It can also act as a barrier to prevent chemical migration from the mask element to the relief-forming precursor when they are in complete optical contact.

When present, the transparent polymeric overcoat layer can be attached directly to the IL and can have an average dry thickness of at least 0.05 μm and up to and including

Forming Mask Elements

In some embodiments, a mask can be formed by producing exposed and non-exposed regions in the IL of the mask precursor described herein. The choice of imaging mechanism will determine the possible variations in forming the mask image, as described below.

Exposing the mask precursor to ablative light energy to ablate the IL layer can be carried out in selected regions, otherwise known as “imagewise exposure.” In some embodiments, imagewise exposure can be accomplished using thermal radiation from a thermal or infrared laser that is scanned or rasterized under computer control. Any of the known scanning devices can be used including flat-bed scanners, external drum scanners, and internal drum scanners. In these devices, the mask precursor material is secured to the drum or bed, and the laser beam is focused to a spot that can impinge on the IL of the mask precursor material. Two or more lasers can scan different regions of the IL simultaneously.

For example, the mask precursor material can be exposed to infrared radiation, for example, in the electromagnetic wavelength range of at least 700 and up to and including 1500 nm. Such mask precursor materials contain one or more second infrared radiation absorbing materials in the IL as described above to provide sensitivity to infrared radiation. In these embodiments, the mask precursor material can be suitably mounted to an infrared imager and exposed to the infrared radiation using an infrared laser such as a diode laser or Nd:YAG laser that can be scanned under computer control. Suitable infrared imagers include but are not limited to TRENDSETTER imagesetters and ThermoFlex Flexographic CTP imagers available from Eastman Kodak Company used for CTP lithographic plate applications and for imaging flexographic elements, DIMENSION imagesetters available from Presstek (Hudson, N.H.) useful for CTP lithographic plate applications, CYREL® Digital Imager (CDI SPARK) available from Esko-Graphics (Kennesaw, Ga.), and OMNISETTER imagers available from Misomex International (Hudson, N.H.) useful for imaging flexographic elements.

This exposing step is illustrated for some embodiments in FIG. 1A in which mask precursor material 10 is exposed to exposing infrared radiation 35 in an imagewise pattern to provide exposed regions 40 and non-exposed regions 42 as illustrated in mask element 36 shown in FIG. 1B and corresponding to a mask image. As shown, the exposed regions 40 are ablated and are removed from the non-exposed regions 42. As such, the exposed regions form the mask image.

The step of forming the mask image can also include a step of removing either exposed or non-exposed regions from the IL if desired. In some embodiments, exposed regions of the IL are removed for example by ablating away the exposed material(s) in the IL. In this mechanism, the exposed regions of the IL are removed from the mask element by the generation of a gas during ablation to leave a mask image. Specific binders (e.g., non-crosslinked) that decompose upon exposure to heat (such as that produced by IR laser irradiation) to rapidly generate a gas can be present in the IL. This action is to be distinguished from other mass transfer techniques in that a chemical rather than a physical change causes an almost complete transfer of the IL rather than a partial transfer.

In other embodiments not illustrated, a mask image can be formed on the carrier sheet (and LTHC layer disposed thereon) by producing exposed and non-exposed regions in the IL and selectively removing the non-exposed regions.

In some embodiments, the mask image in the IL of the mask element can be cured by subjecting it to heat treatment, provided that the properties of the mask element are not adversely affected. Heat treatment can be carried out by a variety of means including but not limited to, storage in an oven, hot air treatment, or contact with a heated platen or passage through a heated roller device. Heat treatment is not necessary for curing to take place.

In still other embodiments, a mask image can be formed in the IL as noted above and the exposed regions can be transferred to a receptor sheet that is then removed from the mask element before it is brought into contact with to a relief-forming precursor. Such procedures are well known in the art.

In a peel-apart imaging mechanism, the exposed regions of the IL can be removed from the carrier sheet (and LTHC layer disposed thereon) using a suitable receptor sheet based on differential adhesion properties in the IL. After imagewise exposure of the mask precursor, the receptor sheet is separated from the carrier sheet and either exposed or non-exposed regions remain in the mask element.

Forming Relief Images

After a mask element and relief-forming precursor are both formed as described above, the mask element is brought into complete optical contact with the relief-forming precursor that includes the photosensitive layer having the low surface energy additive and that is sensitive to curing UV radiation. This protocol can be accomplished by placing the mask element onto the relief-forming precursor or vice versa, as described below in more detail. For example, the contact and coupling of the mask element to the relief-forming precursor can be performed by using lamination equipment and processing. Vacuum drawdown of the mask element onto the relief-forming precursor can also be carried out, with or without lamination, to achieve desired complete optical contact.

Some embodiments according to the present invention can be understood by reference to the general illustrations provided in the sequence of FIG. 1A through FIG. 1E. As described above, FIG. 1A illustrates mask precursor 10 that is exposed to exposing infrared radiation 35 to form mask element 36 (FIG. 1B).

In FIG. 1C, mask element 36 includes the IL layer 15 over the LTHC layer 20 (e.g., with non-ablatable particles) that is over the ablated IL layer 30 that has the mask image formed therein. The mask element 36 is shown in intimate or complete optical contact with a relief-forming precursor 55 to provide relief-image forming assembly 50. Relief-forming precursor 55 includes the UV-sensitive layer 60 (e.g., photosensitive relief-forming layer having the low surface energy additive and that is sensitive to curing UV radiation) that is typically carried on substrate 65.

FIG. 1D shows the step of exposing the relief-image forming assembly 50 to UV radiation 70 shown by the arrows. The UV radiation 70 passes through the transparent polymeric carrier sheet 15, the LTHC layer 20, and the exposed regions (e.g., element 40—removed IL layer portions) of IL 30 in the mask element 36 to cause photocuring in UV-sensitive layer 60 of the relief-forming precursor 55.

After the UV-exposure, mask element 36 can be removed from the UV-sensitive layer 60 of the relief-forming precursor 55 and a development protocol can provide a relief image (FIG. 1E) in the UV-sensitive layer 60. As shown, the relief image includes relief image peaks 75 and relief image valleys 80 in the UV-sensitive layer 60.

Lamination

As noted above, the mask element and relief-forming precursor can be placed in complete optical contact so as to provide an air-free interface at the shared interface. Generally, this is achieved by laminating the mask element to the UV-sensitive layer of the relief-forming precursor by applying suitable pressure or heat, or both pressure and heat to form an air-free or gap-free interface prior to UV exposure. However, when the relief-forming precursor includes the UV-sensitive layer 60 having the low surface energy additive as described above, the laminating procedure may be not needed. As noted above, vacuum drawdown of the masking element onto the relief-forming precursor can then be useful.

Commercially available laminators that provide both heat and uniform pressure can be used including but not limited to, KODAK model 800XL APPROVAL LAMINATOR available from Eastman Kodak Company (Rochester, N.Y.). CODOR LPP650 LAMINATOR available from CODOR (Amsterdam, Holland), and LEDCO HD laminators available from Filmsource (Casselbury, Fla.) can also be useful. If a transparent polymeric overcoat layer is attached directly to the IL of the mask element material, it can be removed before lamination or other operations of forming complete optical contact of mask element with the relief-forming precursor. The relief-image forming assembly formed by coupling the mask element and the relief-forming precursor can be fed into the laminator at a desired speed, temperature, and pressure.

Useful lamination (laminator) devices and methods for using them are described for example in U.S. Pat. No. 7,802,598 (Zwadlo et al.), the disclosure of which is incorporated herein by reference. As noted therein, a pre-press flexographic plate laminator can be used to laminate a mask element (“masking film”) on a relief-forming precursor (“pre-press flexographic printing plate”) by applying a balanced, non-distorting, optimized laminating force to achieve complete optical contact while minimizing lateral distortion.

In some embodiments, the relief-forming precursor does not have a separation layer, spacer layer, or anti-tack layer over the UV-sensitive relief-forming layer, and thereby pressure alone can be sufficient to achieve an air-free interface, as the relief-forming layer having the low surface energy additive within the relief-forming layer can still be tacky, or act as a pressure sensitive adhesive, due to the presence of polymerizable monomers. The amount of the low surface energy additive can be modulated within the parameters defined herein to obtain a desired or optimal amount of tackiness. Too much low surface energy monomer can cause a less tacky surface, and then hot lamination may be used to provide the optical contact coupling with the mask.

UV Exposure

After complete optical contact has been achieved between the mask element and the relief-forming precursor as described above, the relief-forming precursor can be exposed to curing UV radiation through the mask element to form an imaged relief-forming precursor with exposed regions and non-exposed regions in the UV-sensitive layer. The exposed regions are cured and solidified by polymerization of the monomers in the UV-sensitive layer. The non-exposed regions remain uncured and the monomers are not polymerized. Thus, the uniformly emitted curing UV radiation is projected onto the relief-forming precursor through the mask image that preferentially blocks some of the ultraviolet radiation by the remaining portions of the IL layer. In unmasked (exposed) regions, the curing UV radiation will cause hardening or curing of the UV-sensitive composition(s) in the IL. The mask image is therefore substantially opaque to the exposing or curing UV radiation, meaning that the mask image should have a transmission optical density of 2 or more and typically 3 or more in the non-exposed regions. The remaining portion of the IL layer still include the UV sensitive material to absorb the UV light and block it. The unmasked (exposed) regions of the UV-sensitive composition can be substantially transparent meaning that they should have a transmission optical density of 0.5 or less, or even 0.1 or less, and more typically at least 0.5 and up to and including 0.1 or at least 0.1 and up to and including 0.3. Transmission optical density can be measured using a suitable filter on a densitometer, for example, a MACBETH TR 927 densitometer.

Generally, exposure of the relief-forming precursor through the mask element is accomplished by floodwise exposure from suitable irradiation sources of UV radiation. Exposure can be carried out in the presence of atmospheric oxygen. Exposure under vacuum is not necessary as complete optical contact has already been made.

In the manufacture of a relief imaging element, such as a flexographic printing plate, one side of the relief-forming precursor can be generally first exposed to curing UV radiation through its transparent substrate (known as “back exposure”) to prepare a thin, uniform cured layer (e.g., relief image valleys 80) on the substrate side of the UV-sensitive layer. The relief-forming precursor is then exposed to curing UV radiation through the mask element containing the mask image, thereby causing the UV-sensitive to harden or cure in the unmasked (exposed) regions. Unexposed and uncured regions of the UV-sensitive layer can then be removed by a developing process (described below), leaving the cured or hardened regions (e.g., relief image peaks 75) that define the relief image printing surface of a predetermined desired pattern of shapes and sizes of peaks 75 and valleys 80. The back exposure can be performed either before or after complete optical contact is made between the mask element and the relief-forming layer.

The wavelength or range of wavelengths suitable as the curing UV radiation will be dictated by the electromagnetic sensitivity of the relief-forming layer. In some embodiments, the UV curing radiation can have one or more wavelengths in the range of at least 150 nm and up to and including 450 nm, or more typically of at least 300 nm and up to and including 450 nm. Sources of UV radiation for floodwise or overall exposure include but are not limited to, carbon arcs, mercury-vapor arcs, fluorescent lamps, electron flash units, and photographic flood lamps. UV radiation is particularly useful from mercury-vapor lamps and sun lamps. Representative UV radiation sources include SYLVANIA 350 BLACKLIGHT fluorescent lamp (FR 48T12/350 VL/VHO/180, 115 watts) that has a central emission wavelength of about 354 nm that is available from Topbulb (East Chicago, Ind.), and BURGESS EXPOSURE FRAME, Model 5K-3343V511 with ADDALUX 754-18017 lamp available from Burgess Industries, Inc. (Plymouth, Mass.).

Other suitable sources of UV radiation include platemakers that can be used to both expose the relief-forming precursor to radiation and to develop the imaged relief-forming material after radiation exposure. Examples of suitable platemakers include but are not limited to, KELLEIGH MODEL 310 PLATEMAKER available from Kelleigh Corporation (Trenton, N.J.) and the GPP500F PLATE PROCESSOR available from Global Asia Ltd. (Hong Kong).

The time for exposure through the mask element will depend upon the nature and thickness of the UV-sensitive layer of the relief-forming precursor and the source of the and strength of the UV radiation. For example, in one of embodiment, a FLEXCEL-SRH plate precursor available from Eastman Kodak Company can be mounted on a KELLEIGH MODEL 310 PLATEMAKER and back exposed to UV-A radiation through the transparent support for about 20 seconds to prepare a thin, uniform cured layer on the support side of the relief-forming precursor. The relief image forming assembly of mask element and relief-forming precursor can then be exposed to UV radiation through the mask element for about 14 minutes. The mask image information is thus transferred to the relief-forming precursor (such as a flexographic plate precursor).

Separating Mask from UV-Sensitive Layer

In general, the methods described herein can also include removing the mask element from complete optical contact with the imaged relief-forming precursor after the UV exposure and before developing. This can be done using any suitable manner, such as peeling the two elements apart. For example, this can be accomplished by pulling the mask element away from the imaged relief-forming precursor.

In some embodiments, after the UV exposure, the mask element can be removed from the relief-forming layer by peeling the mask element from the relief-forming layer. This can be performed by providing support to one of the mask element or relief-forming precursor, and then applying a pulling force to an edge or end of the other of the mask element or relief-forming precursor (e.g., the relief-forming layer). The low surface energy additive can provide for the lower surface energy and lower peel force so that the separation is easier without damaging the mask element of the relief-forming layer. As such, the peeling or separation facilitated by the lower surface energy and lower peel force can inhibit delamination of the mask element, which allows for the mask element to be reused. Also, the lower surface energy and lower peel force can inhibit degradation and undesirable breakage of the peaks of the relief-forming layer.

In some embodiments, the mask element can be delaminated from the relief-forming precursor, such as by being delaminated from the relief-forming layer. In these embodiments, the mask element is laminated to the relief-forming layer. Then, the mask is delaminated from the relief-forming layer after the UV curing. However, such delamination is not intended to indicate that the mask itself delaminates so that the different layers of the mask element are delaminated from each other. Here, the mask element is delaminated in whole from the relief-forming layer due to the presence of the low surface energy additive. Thus, while the mask is delaminated from the relief-forming layer, the mask itself is not delaminated and damaged. Similarly, the relief-forming layer is not delaminated from the relief-forming precursor.

In some embodiments, the relief-forming precursor can omit a transparent release layer on the UV-sensitive layer. Now, the low surface energy additive can provide for the easier release of the mask from the relief-forming precursor. Thus, the UV-sensitive relief-forming layer can be in direct contact with the mask element, such that separation separates the mask directly from the relief-forming layer. The low surface energy additive can reduce the surface energy and adhesion potential so that the separation is clean without damaging either the mask element or the relief-forming precursor.

In some embodiments, the relief-forming layer can allow for less force to be applied during the peeling apart of the mask and the imaged relief-image precursor (e.g., flexographic printing plate precursor). This comparison of less force with the invention is compared to a relief-forming layer without the low surface energy additive. Thus, the low surface energy additive reduces the surface energy and peel force compared to the same composition without the low surface energy additive. The mask can be peeled away from the relief-forming precursor more quickly and completely, leaving little is no residual material. This effect provides more rapid development of the imaged relief-image precursor as there is little or no residual material to inhibit the development process. Because peeling is easier, minimal handling and hold down pressure is needed with the flexographic imaging assembly and the process can be readily carried out at room temperature. Thus, heating during the curing process is not needed.

The flexographic printing plate assembly having the UV-sensitive layer includes a unique combination of materials so that peeling away of the mask can be quick and complete. By “complete”, at least 95% and preferably at least 98%, at least 99%, or 100% of the mask is peeled off, leaving very little or no residual material. The composition of the UV-sensitive layer provides a peel force in relation to a mask element comprising a mask image of less than about 73 g/inch, preferably less than about 60 g/inch, and more preferably less than about 55 g/in). The relief-forming layer may have a peel force relative to the mask that is measurable, such as at least about 1 Win, at least about 5 g/in, or at least about 10 Win.

In some embodiments, the relief-forming layer is a solvent washable plate precursor, and includes a peel force in relation to a mask element comprising a mask image of less than about 73 g/inch, preferably less than about 60 g/inch, and more preferably less than about 55 Win). The relief-forming layer that is solvent washable may have a peel force relative to the mask that is measurable, such as at least about 1 Win, at least about 5 g/in, or at least about 10 g/in.

In some embodiments, the relief-forming layer is a water washable plate precursor, and includes a peel force in relation to a mask element comprising a mask image of less than about 40 g/inch, preferably less than about 30 g/inch, and more preferably less than about 20 Win). The relief-forming layer that is water washable may have a peel force relative to the mask that is measurable, such as at least about 1 g/in, at least about 5 g/in, or at least about 10 g/in.

This peel force value can be measured in which a 2.54 cm wide by 25.4 cm long strip of mask that is laminated to a UV-sensitive layer having the low surface energy additive of a flexographic printing plate that has been UV exposed is mounted on an IMASS SP-2000 slip/peel tester (IMASS Inc., Accord, Mass.) using double stick tape with the printing plate down. The initial edge of the mask is pulled away from the printing plate and mounted in the force gauge. The maximum peel force in g/linear inch (2.54 cm) width of film is measured at a 180° peel angle and a peel speed of 2 cm/sec.

In some embodiments, the mask element containing the mask image is removed from the UV-exposed UV-sensitive relief-forming layer of the flexographic printing plate precursor by peeling it away at the interface of the mask element and relief-forming layer. This peeling process can be carried out as described in U.S. Pat. No. 7,802,598 using vacuum to hold in place. A corner of the mask element is then pulled away from the printing plate at a rate of 2 to 10 cm/sec at peel angle of 150-180° thereby essentially pulling the imaged film back on itself and keeping the imaged film near the vacuum table surface in a continuous motion until the entire mask element is removed from the UV-sensitive layer of the printing plate. In the practice of this invention, at least 95 weight % of the dry mask element is removed in this operation, so that it can be generally said that the mask element is “completely” or substantially completely removed from the exposed radiation curable layer of the precursor. By “complete”, at least 95% and preferably at least 98%, at least 99%, or 100% of the mask is peeled off, leaving very little or no residual material.

Development

After the mask element is removed from the relief-forming layer, the imaged relief-forming precursor is then generally developed with a suitable developer (or processing solution, or “washout solution”) to form a relief image. Development serves to remove the non-exposed (uncured) regions of the UV-sensitive layer, leaving the exposed (cured) regions that define the relief image as shown in FIG. 1E.

Any known organic solvent-based or aqueous-based developer can be used in this processing step including known developers that contain predominantly chlorinated organic solvents. However, other useful developers are predominantly non-chlorinated organic solvents. By “predominantly,” it is meant that more than 50% (by volume) of the developer comprises one or more non-chlorinated organic solvents such as aliphatic hydrocarbons and long chain alcohols (that is alcohols with at least 7 carbon atoms). The remainder of the developers can be chlorinated organic solvents that are known in the art for this purpose.

Certain useful developers are predominantly what are known as “perchloroethylene alternative solvents” (PAS) that are generally volatile organic compounds typically comprised of mixtures of aliphatic hydrocarbons and long-chain alcohols. Examples of such commercially available solvents include but are not limited to, PLATESOLV available from Hydrite Chemical Co. (Brookfield, Wis.), NYLOSOLV® available from BASF (Germany), FLEXOSOL® available from DuPont (Wilmington, Del.), OptiSol® available from DuPont (Wilmington, Del.), and SOLVIT® QD available from MacDermid (Denver, Co.).

Other useful developers are described in U.S. Pat. No. 5,354,645 (Schober et al.), the disclosure of which is incorporated herein by reference, and include one or more of diethylene glycol dialkyl ethers, acetic acid esters or alcohols, carboxylic acid esters, and esters of alkoxy substituted carboxylic acids. Still other useful developers are described in U.S. Pat. No. 6,162,593 (Wyatt et al) described developers comprising diisopropylbenzene (DIPB), and U.S. Pat. No. 6,248,502 (Eklund).

Additional useful developers are described in U.S. Pat. No. 6,582,886 (Hendrickson et al.) and contain methyl esters alone or mixtures of methyl esters and co-solvents such as various alcohols that are soluble in the methyl ester(s). U.S. Patent Application Publication 2010/0068651 (Bradford) describes useful developers containing dipropylene glycol dimethyl ether (DME) alone or in combination with various co-solvents such as alcohols and aliphatic dibasic acid ethers. Still other useful developers are described in U.S. Patent Application Publication 2011/0183260 (Fohrenkamm et al.). Other useful developers are described in U.S. Pat. No. 8,771,925 (Fohrenkamm et al.) which developer includes diisopropylbenzene and one or more organic co-solvents, one of which is an aliphatic dibasic acid ester. Still other useful developers are described in U.S. Pat. No. 9,005,884 (Yawata et al.) which processing solution can include an alkali metal salt of a saturated fatty acid having a carbon number of 12 to 18 and an alkali metal salt of an unsaturated fatty acid having a carbon number of 12 to 18 in a weight ratio of from 20:80 to 80:20 of the first fatty acid salt to the second fatty acid salt.

Still other useful developers are described in copending and commonly assigned U.S. Pat. No. 10,248,025 (Ollmann et al.). Such flexographic developers can comprise: a) a fatty acid composition consisting of one or more saturated or unsaturated fatty acids or alkali metal salts thereof, each saturated or unsaturated fatty acid or alkali metal salt thereof independently having 12 to 20 carbon atoms, the fatty acid composition being present in an amount of at least 0.25 weight % and up to and including 2.0 weight %, and at least 85 weight % of the fatty acid composition is composed of one or more C18 mono- or poly-unsaturated fatty acids or alkali metal salts thereof; b) an aminopolycarboxylic acid or alkali metal salt thereof in an amount of at least 0.05 weight % and up to and including 0.30 weight %; c) a buffer compound in an amount of at least 05 weight % and up to and including 0.60 weight %; and d) water.

Development can be carried out under known conditions such as for at least 1 minute and up to and including 20 minutes and at a temperature of at least 20° C. and up to and including 32° C. The type of developing apparatus and specific developer that are used will dictate the specific development conditions and can be adapted by a skilled worker in the art.

Post-development processing of the relief image in the imaged relief-forming precursor can be suitable under some circumstances. Typical post-development processing includes drying the relief image to remove any excess solvent and post-curing by exposing the relief image to curing radiation to cause further hardening or crosslinking. The conditions for these processes are well known to those skilled in the art. For example, the relief image can be blotted or wiped dry, or dried in a forced air or infrared oven. Drying times and temperatures would be apparent to a skilled artisan. Post-curing can be carried out using the same type of UV-radiation previously used to expose the relief-forming precursor through the imaged mask material.

Detackification (or “light finishing”) can be used if the relief image surface is still tacky. Such treatments, for example, by treatment with bromide or chlorine solutions or exposure to UV or visible radiation, are well known to a skilled artisan.

The resulting relief image can have a depth of at least 2% and up to and including 100% of the original thickness of the UV-sensitive layer (for example, if this layer is disposed on a substrate). For a flexographic printing plate, the maximum dry depth of the relief image can be from at least 150 μm and up to and including 1,000 or typically at least 200 μm and up to and including 500 For a printed circuit board, the UV-sensitive layer can be completely removed in either the exposed or non-exposed regions, to reveal the metal layer underneath. In such elements, the maximum depth of the relief image depends upon the dry thickness of the UV-sensitive layer. Advantageously, in any embodiment, the relief image can have shoulder angles of greater than 50°.

Thus, in some embodiments, the method is carried out where the relief-forming precursor is a UV-sensitive flexographic printing plate precursor and imaging and developing it such precursor to provide a flexographic printing plate that has a relief image layer formed from the relief-forming layer of the relief-forming precursor. Similarly, letterpress printing plates can be prepared from the appropriate precursor elements.

The relief image layer can still include the low surface energy additive integrated or otherwise bonded (e.g., polymerized) to the polymers of the relieve image layer after development. Accordingly, the ready to use relieve image layer can have a low surface energy moiety that is present at the exposed surface. This results in the relieve image layer having an exposed surface with the silicone being exposed, which provides for a relatively lower surface energy as described below.

In some embodiments, the relief image layer can receive ink during the process of creating a relief image with the ink. The ink can be applied to the relief image layer in a suitable amount that helps the ink have printed dot-gain reduction. Accordingly, the relief image having the polymerized low surface energy moiety can facilitate reduction of the printed dot-gain. This overcomes an issue with flexographic printing plates having too high printed dot-gain.

In some embodiments, the relief image layer having the ink can be cleaned to remove the ink for various reasons, such as changing color or cleaning the surface to apply new ink. Also, changing the ink can help remove any particles from the relief image layer that may be generated during the process. The low surface energy moiety can be present at the surface of the relief image layer to facilitate cleaning of the ink and allow for easier removal of the ink from the features (e.g., elevations, valleys, etc.) of the surface after printing. This provides for a clean relief surface so that the plate can be stored and then used again for printing.

One skilled in the art can readily see the various utilities that such inked elements would have in various industries including the flexographic printing of various packaging materials.

### EXAMPLES

Preparation of a Relief-Forming Precursor

Into a double arm sigma mixer heated to 120° C., a polymer/binder is introduced along with the plasticizers. When the plasticizers are absorbed into the binder and the mixture reaches a homogenous or “semi-melt” state, the rest of the premix formulation including the monomers/stabilizers/photoinitiator/inhibitor/colorants/solvent are gradually added as a solution for Comparative Example 1. Additionally, a silicone acrylate monomer, such as a silicone polyetheracrylate (e.g., TEGO RAD 2250 from Evonik, herein referred to as TR2250) is further introduced as a solution of cyclopentanone for the Inventive Examples described herein. As such, the Comparative Examples omit the TR2250 and the Inventive Examples include the TR2250. The composition is continued to mix for 1-1.5 hours until no visible binder particles are seen and the melt is homogenous. The temperature of the mixer may be cut off once the melt has reached the mixing temperature and the material allowed to “cool” in the mixer (to around 75° C.) without mixing for some time before unloading.

Once the material is unloaded from the mixer, a necessary amount of the photosensitive photopolymer mix is measured out and placed between a base film and a cover sheet. An appropriate shim gauge is used to obtain the right thickness of the plate and this shim gauge is placed between the base and cover film. This sandwiched construction (base film, photosensitive photopolymer and the cover film) is then placed in a hot metal press set to ˜240° F. and pressed for 2-3 minutes at a pressure of approximately 20 tons to produce the photosensitive printing plate precursor.

### Comparative Example 1

A formulation is prepared without the low surface energy monomer TR2250. A solvent processable photosensitive flexographic printing plate precursor was prepared following the procedure described above using a photosensitive polymer composition similarly to that described in U.S. Pat. No. 6,897,006, consisting of 60 parts by mass of a triblock co-polymer (trade name Kraton 405), 30.17 parts polybutadiene plasticizers (trade name Nisso PB2000, made by Nippon Soda Co., Ltd., and Polyvest 110 made by Evonik), a total of 0.91 parts by mass of stabilizers and inhibitors (BHT Swanox, Nonflex EBP, Q-1301), 0.13 parts of solvent (THF), 0.92 parts colorants (Diaresin Blue and NBT-1150 Green), 1.34 parts of a benzil dimethyl ketal photoinitiator (Omnirad 651), and a total of 7.69 parts of cross-linkable monomers (HDDA and TMPTA).

### Inventive Example 1

A formulation is prepared with the low surface energy silicone polyetheracrylate, TEGO RAD 2250. A flexographic printing plate photopolymer was obtained as described in Comparative Example 1, however 0.5% of low surface energy silicone polyetheracrylate (TR2250) was also added, and the solvent (THF) was replaced with cyclopentanone as the solvent.

### Comparative Example 2

A commercially available Flexcel NX Ultra, photopolymer plate precursor from Miraclon Corporation, was used as a Comparative Example 2 to the Inventive Example 2.

### Inventive Example 2

To test the effectiveness of a low surface energy monomer (e.g., silicone acrylate) to reduce/improve the delamination of a mask element from a water washable flexographic printing plate precursor, TR2250 was introduced into the Flexcel NX Ultra photopolymer plate precursor (e.g., UV-sensitive material) by scraping off the photosensitive photopolymer mix from a Flexcel NX Ultra photopolymer plate precursor and placing this photopolymer mix in the sigma mixer set to 120° C. The mix quickly reaches a semi melt condition at which point 1 part of TR2250 is added slowly. This composition is then further mixed for an hour before allowing to cool down and finally removed from the mixer. An appropriate amount of the mix, now additionally including TR2250, is then used to obtain a UV-curable material of the flexographic photosensitive plate precursor by the procedure detailed above.

### Comparative Example 3

As a comparative/test example, an amino functionalized silicone oil, Poly(dimethylsiloxane), bis(3-aminopropyl) terminated, from Sigma Aldrich, similar to the amino group functionalized silicone oils as described in U.S. Pat. No. 8,114,566 was incorporated at 0.5 parts into the photosensitive polymer composition of comparative Example 1.

After removal of the cover sheet from the photopolymer plate precursor, an imaged mask was laminated to the front imaging surface (relief-forming layer) of the flexographic printing plate precursor. Lamination was carried out using a commercially available Flexcel NX Wide 5080 Laminator with standard settings to bring the mask element in direct and intimate contact with the front imaging surface of the UV-sensitive layer of the relief-forming precursor. Following lamination, the mask element and relief-forming precursor were uniformly exposed through the backside followed by a frontside image-wise exposure through the mask element. It was observed that there were many bubbles formed at the interface of the mask and the relief-forming layer. Any bubble formation is known to be detrimental to image reproduction from the mask to the UV-sensitive material as it forms a gap between the mask image and the relief-forming material and the intimate contact between the mask and the relief-forming layer is broken. Compared to this, the inventive examples with silicone monomer do not form bubbles.

Peel Force Measurements

Peel force measurements were carried following the process described in U.S. Pat. No. 10,207,491. After removal of the cover sheet from the relief-forming layer of the relief-forming precursor, an imaged mask was laminated to the front imaging surface of the UV-sensitive layer. Lamination was carried out using a commercially available Flexcel NX Wide 5080 Laminator with standard settings to bring the mask element in direct and intimate contact with the front imaging surface of the relief-forming layer. Following lamination, the mask element and relief-forming precursor were uniformly exposed through the backside followed by a frontside imagewise exposure through the mask element. A 2-inch wide sample was cut out for each of the combinations of laminated and exposed articles to use in the peel test for which the relief-forming precursor was adhered to a stainless-steel plate using 3M® brand double-sided clear adhesive tape E1120H. The peel force (in grams) was measured using an IMASS Adhesion Tester SP—2100 (available from Imass, Inc., Hing-ham, Mass.) that was equipped with a 5 kg load, a peel angle of 180°, and a peel rate of 12 inches/minute. The measurements were averaged over 5 seconds and a 1 second delay.

Formation of a Flexographic Printing Plate with Relief Image

After removal of the cover film from the relief-forming layer of the relief-forming precursor, followed by lamination of a mask and UV curing as described above, the mask is removed from the photosensitive layer either manually or by a mechanical process. The relief-image precursor with the relief image in the relief-forming layer is then processed using a solvent or an aqueous plate processing agent depending on the nature of the photopolymer plate precursor, dried and finished (post UV exposures) to obtain a relief printing plate.

Surface Energy Measurements:

To derive the surface energy values for the relief flexographic printing plates, contact angles were first measured using polar (water) and dispersive (diiodomethane) droplets.

The surface energy components for each liquid used are:

Water: γₗ^{D}=21.8 mJ/m\hat{ }2, γₗ^{P}=51 mJ/m\hat{ }2, γₗ^{T}=72.8 mJ/m\hat{ }2;

Diiodomethane: γₗ^{D}=50.8 mJ/m\hat{ }2, γₗ^{P}=0 mJ/m\hat{ }2, γₗ^{T}=50.8 mJ/m\hat{ }2.

Whereby:

γₗ^{D}=dispersive component of surface energy of liquid;

γₗ^{P}=polar component of surface energy of liquid;

γₗ^{T}=total surface energy of liquid.

In order to calculate surface energy, the Fowkes model as well as the Owens-Wendt-Rabel & Kaelble model were used.

$$\sqrt{{γ}_{l}^{D} * {γ}_{s}^{D}} + \sqrt{{γ}_{l}^{P} * {γ}_{s}^{P}} = \frac{{γ}_{l}^{T} ( 1 + cos ( θ )}{2} ; \qquad Equation 1$$

Equation 1: Fowkes equation relating liquid and solid components with contact angle.

Whereby:

γₛ^{D}=dispersive component of surface energy of solid;

γₛ^{P}=polar component of surface energy of solid;

θ=contact angle.

$$\frac{{γ}_{l}^{T} ( 1 + cos ( θ )}{2 ( \sqrt{{γ}_{l}^{D}}} = ( \sqrt{{γ}_{s}^{P}} ) \frac{( \sqrt{{γ}_{l}^{P}} )}{( {γ}_{l}^{D} )} + \sqrt{{γ}_{s}^{D}} \qquad Equation 2$$

Equation 2: Owens-Wendt-Rabel & Kaelble model.

Summary of Surface Energy and Peel Force

The peel force for peeling the mask element from the imaged relief-forming layer of the relief-forming precursor was measured as described herein. Additionally, the relief-forming layer was developed in to a relief image layer for a relief printing plate, and then the surface energy of the relief image layer was measured as described herein.

The Inventive Examples are compared to the Comparative Examples as shown in Table 1.

There is a significant peel force reduction when removing the mask element from the imaged relief-forming layer of the relief-forming precursor. Also, the lower surface energy is obtained with the relief image layer having the low surface energy additive of the relief printing plates compared to the higher surface energy of a relief image layer without the low surface energy additive.

It is evident from Table 1 that for the solvent washable relief-forming precursors, the Inventive Example 1 containing a low surface energy monomer shows a 30% reduction in the amount of force required to peel the mask TIL-R (E.g., mask described in U.S. Pat. No. 8,945,813 (Kidnie) from the plate compared to Comparative Example 1. There is also a 65% reduction of peel force when a mask as described in U.S. No. 2019/0258154 (Kidnie) is used compared to Comparative Example 1. This significant reduction of peel force allows for peeling and removal of the imaged mask from the plate easily, which may enable peeling with a simple mechanical device for auto-removal of the mask from the relief-forming layer.

Also, Table 1 shows that the peel force reduction of 52% for Inventive Example 2 (water washable Ultra NX plate containing a low surface energy monomer) compared to the Comparative Example 2, allows easier peeling of the mask from the water washable relief-forming layer of the flexographic plate precursor, which helps prevent unintended damage to the mask or the relief-forming layer of the relief flexographic printing plate during separation thereof.

| | | Low | | Mask Image Type | |
|---|---|---|---|---|---|
| | | surface | Surface | TIL-R Mask | Mask in |
| | | energy | Energy of | in ‘5813 | ‘8154 |
| | Relief-forming | silicone | relief image | (Kidnie) | (Kidnie) |
| | precursor | monomer | surface | Peel force | Peel Force |
| Comparative | Comparative | None | 60.9 mj/m² | 73.41 g/in | 96.12 g/in |
| Example 1 | solvent | | | | |
| | washable plate | | | | |
| | precursor | | | | |
| Inventive | Inventive | TR2250 | 56.3 mj/m² | 51.05 g/in | 33.85 g/in |
| Example 1 | solvent | (0.5 parts) | | | |
| | washable plate | | | | |
| | precursor | | | | |
| Comparative | Comparative | None | 46.7 mj/m² | 31.3 g/in | — |
| Example 2 | water washable | | | | |
| | plate precursor | | | | |
| Inventive | Water | TR2250 | 42.7 mj/m² | 15.14 g/in | — |
| Example 2 | washable plate | (1.0 parts) | | | |
| | precursor | | | | |

It should be noted that the different types of plates can have different surface energies with the low surface energy additive. That is, the type of matrix material of the relief-forming layer can provide the basis for the surface energy, then adding the low surface energy additive can significantly reduce that surface energy. Accordingly, the reduced surface energy is relative to the same type of material without the low surface energy additive silicone acrylate. Thus, a material, such as Comparative Example 2 has an even further reduced surface energy when the low surface energy additive is included as in Inventive Example 2.

In view of the foregoing, the low surface energy additive can reduce the peel force for the UV-curable relief-forming material for various types of matrix materials. This allows for a certain type of polymerizable monomer to be used for the matrix, and then adding the low surface energy additive reduces the peel force for that certain type of monomer. It should be appreciated that different types of monomers and resulting polymers can all have different peel forces without the low surface energy additive, and adding the low surface energy additive reduces the peel force for each of the different types of monomers and resulting polymers. Correspondingly, the surface energy for one type of polymer may be higher than others; however, the low surface energy additive can reduce the surface energy of these polymers in the formed relief image layer. Thus, the low surface energy additive reduces the peel force for peeling the mask from the UV-sensitive layer and reduces the surface energy of the resulting relieve image layer compared to compositions without the low surface energy additive.

In some embodiments, the peel force can be less than about 73.41 Win for any type of mask type, For solvent washable plate precursors, the peel force can be less than about 70 Win, more preferably less than about 60 g/in, more preferably less than about 55 g/in, and more preferably less than about 50 g/in. For water washable plate precursors, the peel force can be less than about 30 Win, more preferably less than about 25 Win, more preferably less than about 20 Win, and more preferably less than about 15 g/in.

In some embodiments, the surface energy of the relief image layer that is solvent washable can be less than about 60 mj/m², more preferably less than about 58 mj/m², less than about 57 mj/m², or less than or about 56 mj/m². Also, the surface energy of the relief image layer that is water washable can be less than about 46 mj/m², more preferably less than about 45 mj/m², less than about 44 mj/m², or less than or about 43 mj/m².

### Definitions

As used herein to define various components of the non-ablatable light-to-heat converting (LTHC) layer, non-silver halide thermally-ablatable imaging layer (IL), and other materials, layers, and compositions (for example, a developer or processing solution) used in the practice of this invention, unless otherwise indicated, the singular forms “a,” “an,” and “the” are intended to include one or more of the components (that is, including plurality referents).

Each term that is not explicitly defined in the present application is to be understood to have a meaning that is commonly accepted by those skilled in the art. If the construction of a term would render it meaningless or essentially meaningless in its context, the term should be interpreted to have a standard dictionary meaning.

The use of numerical values in the various ranges specified herein, unless otherwise expressly indicated otherwise, are considered to be approximations as though the minimum and maximum values within the stated ranges were both preceded by the word “about.” In this manner, slight variations above and below the stated ranges may be useful to achieve substantially the same results as the values within the ranges. In addition, the disclosure of these ranges is intended as a continuous range including every value between the minimum and maximum values as well as the end points of the ranges.

The non-ablatable light-to-heat converting layer is also identified herein as the LTHC layer.

The non-silver halide thermally-ablatable imaging layer is also identified herein as the IL.

Unless indicated herein, the term “imageable material” is used to refer to embodiment articles prepared and used according to the present invention. Such imageable materials can also be known as “mask films,” “mask precursors,” or “masking elements.” The imageable material can be transformed into a “mask element” with suitable thermal (IR) imaging, which mask element contains a mask image that can be used to form a relief image according to the present invention.

Unless otherwise indicated, percentages are by weight.

The term “relief-forming precursor” used herein refers to any imageable element or imageable material in which a relief image can be produced by exposure through a mask element. Examples of such relief-forming precursors are described in detail below but some relief-forming precursors include flexographic printing plate precursors, letterpress printing plate precursors, and printed circuit boards. Details of useful relief-forming materials are described in U.S. Patent Application Publication 2005/0227182 (noted above), the disclosure of which is incorporated herein by reference. In this publication, the relief-forming precursors are generally identified as “radiation-sensitive elements.”

Unless otherwise indicated, the term “ablative” or “ablation” refers to thermal imaging by means of a laser that causes rapid local changes in the non-silver halide thermally-ablatable imaging layer (IL) of an imageable material thereby causing the material(s) in the IL to be ejected from the IL. This is distinguishable from other material transfer or imaging techniques such as melting, evaporation, or sublimation.

The terms “optical contact” and “complete optical contact” have the same meaning and refer to two layers or two elements (as in the case of the mask element and a relief-forming precursor) sharing an interface and being in intimate physical contact so that there is essentially no air-gap or void between the contacting surfaces, thus providing an “air-free interface.” More precisely, two surfaces are defined as being in optical contact when the reflection and transmission characteristics of their interface are essentially fully described by the Fresnel laws for the reflection and transmission of light at the refractive-index boundary.

Unless otherwise noted, the term “transparent” used herein refers to the ability of a material or layer to transmit at least 95% of impacting (or incident) electromagnetic radiation, such as electromagnetic radiation having a wavelength of at least 200 nm to and including 750 nm (that is, what are generally known in the art as UV and visible radiation). The transparent polymeric carrier sheet and LTHC layer described below particularly have this property.

“Average dry thickness” of a given dry layer is generally an average of 10 different measurements of a dry cross-sectional image of that layer.

One skilled in the art will appreciate that, for the processes and methods disclosed herein, the functions performed in the processes and methods may be implemented in differing order. Furthermore, the outlined steps and operations are only provided as examples, and some of the steps and operations may be optional, combined into fewer steps and operations, or expanded into additional steps and operations without detracting from the essence of the disclosed embodiments.

The present disclosure is not to be limited in terms of the particular embodiments described in this application, which are intended as illustrations of various aspects. Many modifications and variations can be made without departing from its spirit and scope, as will be apparent to those skilled in the art. Functionally equivalent methods and apparatuses within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds compositions or biological systems, which can, of course, vary. It is also to be understood that the terminology used herein is for the purpose of describing particular embodiments only, and is not intended to be limiting.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations. In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, such as in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” and the like include the number recited and refer to ranges which can be subsequently broken down into subranges as discussed above. Finally, as will be understood by one skilled in the art, a range includes each individual member. Thus, for example, a group having 1-3 cells refers to groups having 1, 2, or 3 cells. Similarly, a group having 1-5 cells refers to groups having 1, 2, 3, 4, or 5 cells, and so forth.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

All references recited herein are incorporated herein by specific reference in their entirety.

1. A relief-forming precursor comprising:
a substrate; and
a relief-forming layer having a bottom surface facing the substrate and a relief-forming surface facing away from the substrate, the relief-forming layer comprising:
a polymer;
at least one photopolymerizable monomer;
a photopolymerization initiator; and
a low surface energy monomer.

2. The relief-forming precursor of claim 1, wherein the low surface energy monomer has a silicone moiety linked to at least one polymerizable functional group.

3. The relief-forming precursor of claim 2, wherein the at least one polymerizable functional group includes at least one type of acrylate moiety.

4. The relief-forming precursor of claim 3, wherein the at least one type of acrylate moiety includes an acrylate or a methacrylate.

5. The relief-forming precursor of claim 2, the low surface energy monomer further comprising a plurality of polymerizable functional groups linked to the silicone moiety.

6. The relief-forming precursor of claim 1, consisting essentially of in order:
the substrate;
an optional metal layer on the substrate;
a single layer of the relief-forming layer on the substrate or metal layer; and
an optional coversheet on the relief-forming layer.

7. A relief-forming assembly comprising:
the relief-forming precursor of claim 1; and
a mask element having an imaged layer with a mask image, the mask element being in complete optical contact with the relief-forming surface of the relief-forming layer.

8. The relief-forming assembly of claim 7, wherein the low surface energy monomer has a silicone moiety linked to at least one polymerizable functional group.

9. The relief-forming assembly of claim 8, wherein the at least one polymerizable functional group includes at least one type of acrylate moiety.

10. The relief-forming assembly of claim 9, wherein the at least one type of acrylate moiety includes an acrylate or a methacrylate.

11. The relief-forming assembly of claim 7, further comprising an adhesive layer on the substrate opposite of the relief-forming layer.

12. The relief-forming assembly of claim 11, further comprising an anti-halation material in adhesive layer.

13. The relief-forming assembly of claim 7, consisting essentially of in order:
the substrate;
an optional metal layer on the substrate;
a single layer of the relief-forming layer on the substrate or metal layer; and
the mask element.

14. A method of making the relief-forming assembly of claim 7, comprising:
placing an imaged layer of the mask element on the relief-forming surface of the relief-forming layer; and
forming the complete optical contact between the mask element and the relief-forming surface.

15. The method of claim 14, further comprising at least one of:
laminating the mask element to the relief-forming surface; or
vacuum drawdown coupling the mask element to the relief-forming surface.

16. A method of making a relief image in a relief-forming assembly, the method comprising:
providing the relief-forming assembly of claim 7;
exposing the relief-forming layer to curing UV radiation through the mask element to form an imaged relief-forming layer with UV-exposed regions forming polymerized regions and non-exposed regions forming non-polymerized regions in the imaged relief-forming layer;
removing the mask element from the imaged relief-forming layer; and
developing the imaged relief-forming layer by removing the non-polymerized regions in the imaged relief-forming layer, thereby forming a relief image element having a relief image.

17. The method of claim 16, further comprising polymerizing the at least one photopolymerizable monomer and the low surface energy monomer with the photopolymerization initiator such that a low surface energy moiety is present at a relief surface of the relief image of the relief image element.

18. The method of claim 17, further comprising polymerizing a plurality of polymerizable functional groups of the low surface energy monomer with the at least one photopolymerizable monomer so as to form a crosslinked polymer relief image element.

19. The method of claim 17, wherein the low surface energy monomer has a silicone moiety linked to at least one polymerizable functional group.

20. The method of claim 19, wherein the at least one polymerizable functional group includes at least one type of acrylate moiety.

21. A relief-image element comprising:
a substrate
an relief image layer having an elastomer and copolymer, wherein the copolymer includes at least one photopolymerized monomer and a low surface energy monomer that has a silicone moiety, wherein a relief surface of the relief image layer has elevations and valleys of a relief image, wherein a portion of the silicone moiety is present at the relief surface.

22. The relief-image element of claim 21, wherein the copolymer includes a crosslinking of the photopolymerized monomer and low surface energy monomer.
